(19) United States
(12) Patent Application Publication
(10) Pub. No.: US 2025/0057010 A1
(43) Pub. Date: Feb. 13, 2025

(54) DISPLAY DEVICE

(71) Applicant: Samsung Display Co., LTD., Yongin-si (KR)

(72) Inventor: SUNGWON KIM, Yongin-si (KR)

(21) Appl. No.: 18/624,737

(22) Filed: Apr. 2, 2024

(30) Foreign Application Priority Data
Aug. 9, 2023 (KR) 10-2023-0103979

(51) Int. Cl. H10K 59/80; H10K 102/00

(52) U.S. Cl. CPC H10K 59/872; H10K 2102/311

(57) ABSTRACT

A display device includes a display panel, a window that is disposed on the display panel and that includes a flat window part and a flexible window part that extends from the flat window part and that is folded such that a portion of the flexible window part is disposed under the flat window part, and a support plate disposed under the display panel. The flexible window part includes a pattern part including a first surface on which a first groove is defined and a second surface opposite to the first surface, the second surface facing the display panel, and a cover that covers the first groove.

This application claims priority to Korean Patent Application No. 10-2023-0103979, filed on Aug. 9, 2023, and all the benefits accruing therefrom under 35 U.S.C. § 119, the content of which in its entirety is herein incorporated by reference.

### BACKGROUND

### 1. Field

Embodiments of the present invention described herein relate to a display device, and more particularly to a display device which prevents a pattern of a window, flexibly folded together with a display panel, from being visible.

### 2. Description of Related Art

In general, electronic devices, such as a smart phone, a digital camera, a notebook computer, a car navigation unit, a smart television, and the like, which provide an image to a user include a display device for displaying an image. The display device generates an image and provides the generated image to the user through a display screen.

With the development of display device technology, various types of display devices are being developed. For example, a flexible display device that is able to be slid or wound to extend outside of a case is being developed. The flexible display device that is able to be deformed in various ways may be easy to carry and may improve user convenience.

The flexible display device includes a display panel, a window disposed on the display panel, and a support part disposed under the display panel. The display panel, the window, and the support part are accommodated in the case and are extended by being extracted from the case to the outside as needed. The display panel may be a flexible display panel and may be deformed into various shapes.

### SUMMARY

Embodiments of the present invention provide a display device for preventing a pattern of a window flexibly folded together with a display panel from being visible.

According to an embodiment, a display device includes a display panel, a window that is disposed on the display panel and that includes a flat window part and a flexible window part that extends from the flat window part, wherein the flexible window part is folded such that a portion of the flexible window part is disposed under the flat window part, and a support plate disposed under the display panel. The flexible window part includes a pattern part including a first surface on which a first groove is defined and a second surface disposed opposite to the first surface, the second surface facing the display panel, and a cover that covers the first groove.

According to an embodiment, a display device includes a display panel and a window disposed on the display panel. The window includes a flat window part, a pattern part that extends from the flat window part, wherein the pattern part includes a first surface on which a first groove is defined and a second surface disposed opposite to the first surface, the second surface facing the display panel, and a cover that covers the first groove.

### BRIEF DESCRIPTION OF THE FIGURES

The above and other objects and features of the present invention will become apparent by describing in detail embodiments thereof with reference to the accompanying drawings.

FIG. 1 is a perspective view of a display device, according to an embodiment.

FIG. 2 is a perspective view of the display device of FIG. 1 for explaining an extended mode according to an embodiment.

FIG. 3 is a plan view of a display module accommodated in a case illustrated in FIG. 1, according to an embodiment.

FIG. 4 is a perspective view of the display module illustrated in FIG. 3 in a folded state, according to an embodiment.

FIG. 5 is a sectional view of the display module of FIG. 3 taken along line I-I′ illustrated in FIG. 3, according to an embodiment.

FIG. 6 is a sectional view illustrating a configuration of the display panel illustrated in FIG. 5, according to an embodiment.

FIG. 7 is a sectional view illustrating a configuration of the display panel illustrated in FIG. 6, according to an embodiment.

FIG. 8 is a plan view of the display panel illustrated in FIG. 7, according to an embodiment.

FIG. 9 is a perspective view of the display module illustrated in FIG. 3 and a support part supporting the display module, according to an embodiment.

FIG. 10 is an enlarged view illustrating a portion of one of the support bars illustrated in FIG. 9 and a link bar disposed adjacent to the support bar, according to an embodiment.

FIG. 11 is a sectional view of the display module and the support bar of FIG. 9 taken along line II-II′ illustrated in FIG. 9, according to an embodiment.

FIG. 12 is a side view illustrating a configuration in which the display module and the support plate illustrated in FIG. 9 are bonded to each other, according to an embodiment.

FIG. 13 is a bottom view illustrating a folded state of the display module and the support plate in a state in which the display module, the support plate, the support bars, and the link bars illustrated in FIG. 9 are coupled, according to an embodiment.

FIG. 14 is an exploded perspective view of the case illustrated in FIG. 1, according to an embodiment.

FIG. 15 is a perspective view for explaining a configuration in which the link bars illustrated in FIGS. 9, 10, 11, and 13 are coupled to a guide rail, according to an embodiment.

FIG. 16 is a sectional view illustrating a state in which the link bars illustrated in FIG. 15 are coupled to the guide rail, according to an embodiment.

FIG. 17 is a perspective view illustrating a state in which a flat part of the support part illustrated in FIG. 9 is disposed on a sub-support part illustrated in FIG. 14, according to an embodiment.

FIG. 18 is a sectional view of the case of FIG. 14 taken along line III-III′ illustrated in FIG. 14, according to an embodiment.

FIG. 19A is a sectional view of the case of FIG. 14 taken along line IV-IV′illustrated in FIG. 14, according to an embodiment.

FIG. 19B is a sectional view of the case of FIG. 14 taken along line IV-IV′ illustrated in FIG. 14, according to an embodiment.

FIG. 20 is a sectional view of the case of FIG. 14 taken along line V-V′ illustrated in FIG. 14, according to an embodiment.

FIG. 21 is a side sectional view of the case of FIG. 14 taken along line VI-VI′ illustrated in FIG. 14, where FIG. 21 illustrates a default mode of the display device illustrated in FIG. 1, according to an embodiment.

FIG. 22 is a sectional view of the case of FIG. 14 taken along line VI-VI′ illustrated in FIG. 14, where FIG. 22 illustrates the extended mode of the display device illustrated in FIG. 2, according to an embodiment.

FIG. 23 is a side view of a window illustrated in FIG. 5 as viewed in a second direction, according to an embodiment.

FIG. 24 is a plan view of the window illustrated in FIG. 23 as viewed from above, according to an embodiment.

FIG. 25 is a perspective view of the flexible window part illustrated in FIG. 23, according to an embodiment.

FIG. 26 is an enlarged view of a portion of the flexible window part illustrated in FIG. 23, according to an embodiment.

FIG. 27 is a side view illustrating a folded state of the window illustrated in FIG. 23, according to an embodiment.

FIG. 28A is a view for explaining a window manufacturing method, according to an embodiment.

FIG. 28B is a view for explaining a window manufacturing method, according to an embodiment.

FIG. 29A is a view for explaining a window manufacturing method, according to an embodiment.

FIG. 29B is a view for explaining a window manufacturing method, according to an embodiment.

FIG. 30 is a view illustrating a comparison window, according to a comparative embodiment.

FIG. 31 illustrates an image of a front surface of a display module including the comparison window illustrated in FIG. 30, according to an embodiment.

FIG. 32 illustrates an image of a front surface of the display module including the window illustrated in FIG. 23, according to an embodiment.

FIG. 33 is a view illustrating a configuration of a window, according to an embodiment.

FIG. 34 is an enlarged view of a portion of a flexible window part illustrated in FIG. 33, according to an embodiment.

FIG. 35 is a view illustrating a configuration of a window, according to an embodiment.

FIG. 36 is a view illustrating a configuration of a window, according to an embodiment.

### DETAILED DESCRIPTION

In this disclosure, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the invention, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

Unless otherwise defined, all terms used herein, including technical or scientific terms, have the same meanings as those generally understood by those skilled in the art to which the invention pertains. Such terms as those defined in a generally used dictionary are to be interpreted as having meanings equal to the contextual meanings in the relevant field of art and are not to be interpreted as having ideal or excessively formal meanings unless clearly defined as having such in the present application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

The expression “directly disposed” as used herein may mean that there is no additional layer, film, area, or plate between one portion, such as a layer, a film, an area, or a plate, and another portion. For example, the expression “directly disposed” may mean that two layers or two members are disposed without an additional member such as an adhesive member therebetween.

Terms such as “part” and “unit” mean a software component or hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, program code segments, drivers, firmware, microcode, circuits, data, database, data structures, tables, arrays, or variables.

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Hereinafter, embodiments of the invention will be described with reference to the accompanying drawings.

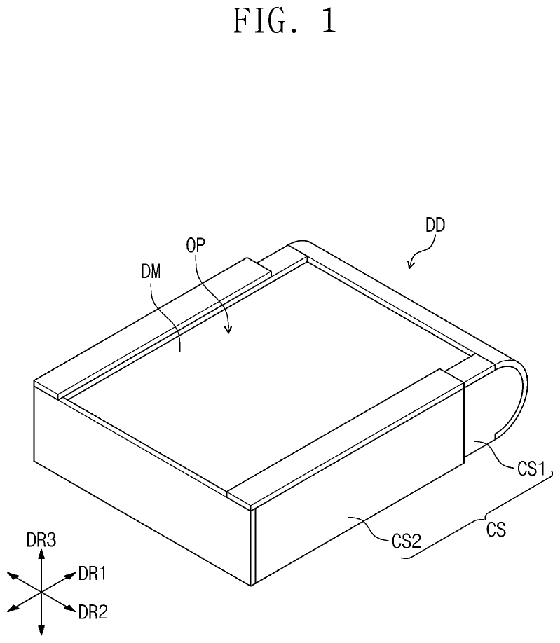

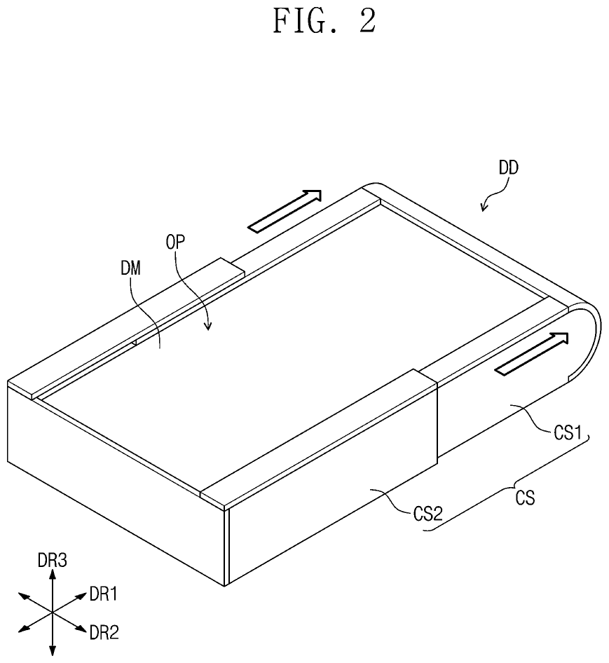

FIG. 1 is a perspective view of a display device, according to an embodiment. FIG. 2 is a view for explaining an extended mode of the display device illustrated in FIG. 1, according to an embodiment.

Referring to FIG. 1, the display device DD, according to an embodiment, may include a display module DM and a case CS accommodating the display module DM. The display module DM may be exposed to the outside through an opening OP defined in an upper portion of the case CS.

In an embodiment, the case CS may include a first case CS1 and a second case CS2 that are coupled with each other and that accommodate the display module DM. The first case CS1 may be coupled to the second case CS2 to move in a first direction DR1.

Hereinafter, a direction crossing the first direction DR1 is defined as a second direction DR2. A direction substantially perpendicular to a plane defined by the first and second directions DR1 and DR2 is defined as a third direction DR3. As used herein, the expression “when viewed from above the plane” may mean that it is viewed in the third direction DR3.

In an embodiment and referring to FIGS. 1 and 2, the first case CS1 may move toward or away from the second case CS2 in the first direction DR1. When the first case CS1 moves in the first direction DR1, the area of an exposed surface of the display module DM may be adjusted depending on the movement of the first case CS1.

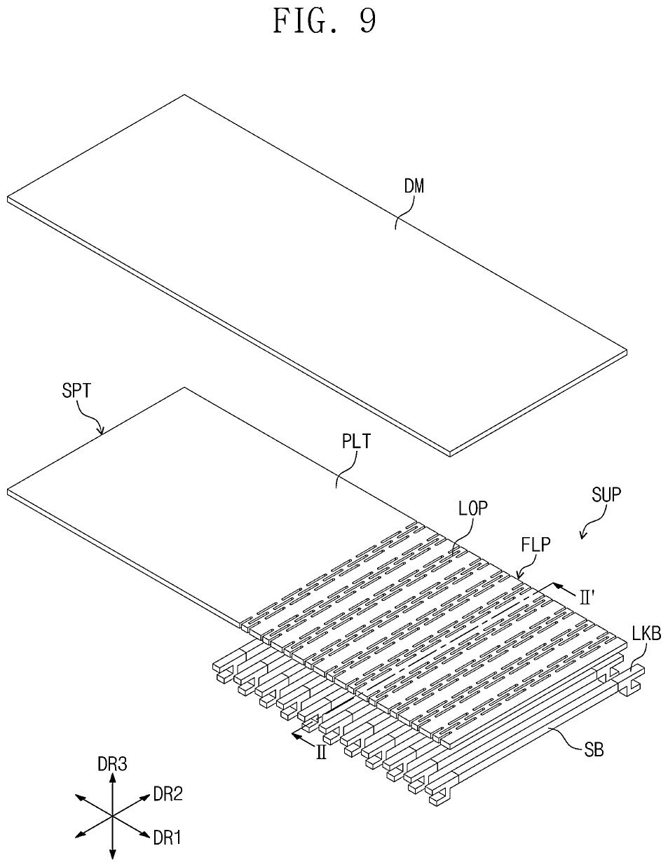

In an embodiment, the display module DM may be a flexible display module and may be supported by a support part disposed under the display module DM. A detailed structure of the support part will be described below in detail with reference to FIG. 9.

In an embodiment, the display module DM and the support part may be accommodated in the first case CS1 and the second case CS2. The display module DM and the support part may be connected to the second case CS2, and when the first case CS1 moves away from the second case CS2 in the first direction DR1, the display module DM and the support part may also move in the first direction DR1.

Although not illustrated, in an embodiment, a portion of the display module DM not exposed to the outside in addition to a portion of the display module DM exposed through the opening OP may be disposed in the first case CS1.

In an embodiment and referring to FIG. 2, the first case CS1 may move away from the second case CS2 in the first direction DR1. The display module DM may move in the first direction DR1 depending on the movement of the first case CS1, and thus the exposed surface of the display module DM may be extended. As the exposed surface of the display module DM is extended, a user may visually recognize an image through a larger screen. The state of the display device DD in which the exposed surface of the display module DM is extended may be defined as an extended mode.

In an embodiment and referring to FIG. 1, the first case CS1 may move toward the second case CS2 in the first direction DR1. When the first case CS1 moves toward the second case CS2 to a maximum, the exposed surface of the display module DM may be set to a minimum. The state of the display device DD may be defined as a default mode. The default mode and the extended mode of the display device DD may be implemented depending on the movement of the first case CS1.

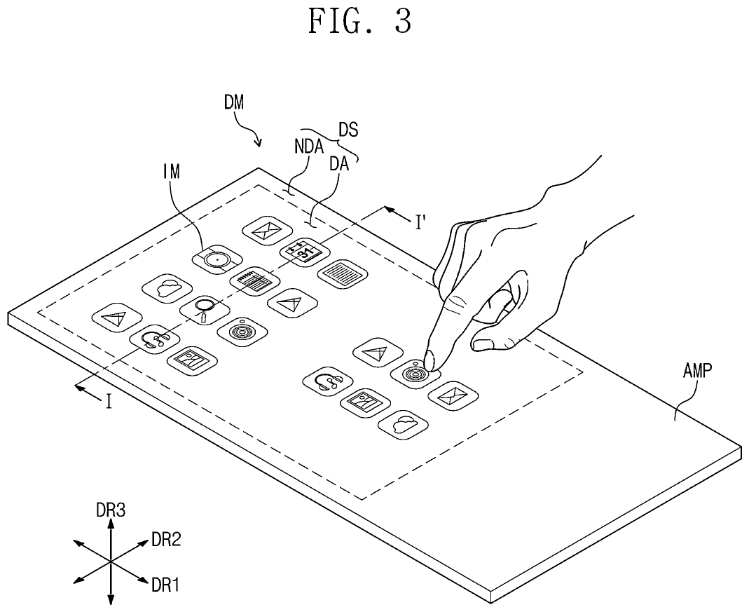

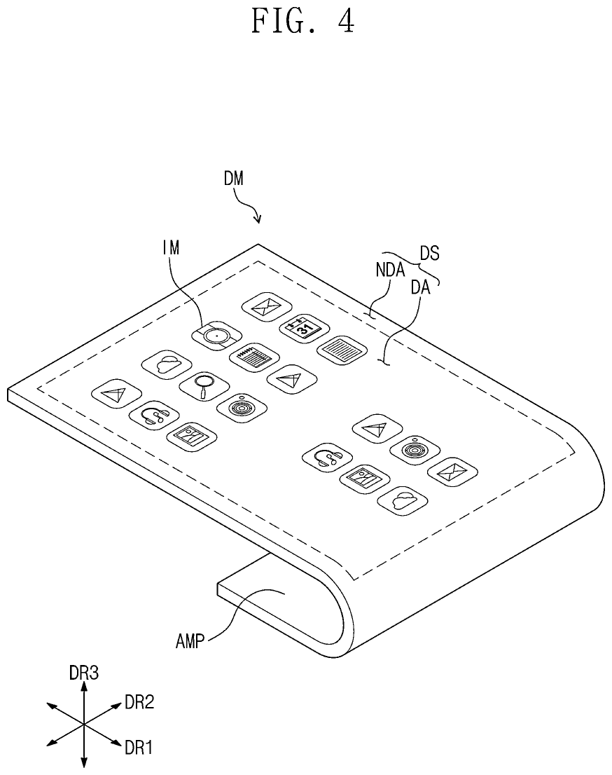

FIG. 3 is a plan view of the display module accommodated in the case illustrated in FIG. 1, according to an embodiment. FIG. 4 is a view illustrating a folded state of the display module illustrated in FIG. 3, according to an embodiment.

In an embodiment and referring to FIG. 3, the display module DM may have a rectangular shape with long sides extending in the first direction DR1 and short sides extending in the second direction DR2. However, without being limited thereto, the display module DM may have various shapes such as a circular shape, a polygonal shape, and the like.

In an embodiment, the upper surface of the display module DM may be defined as a display surface DS and may have a plane defined by the first direction DR1 and the second direction DR2. Images IM generated by the display module DM may be provided to the user through the display surface DS.

In an embodiment, the display surface DS may include a display region DA and a non-display region NDA surround the display region DA. The display region DA may display an image, and the non-display region NDA may not display an image. The non-display region NDA may surround the display region DA and may define the border of the display module DM that is printed in a predetermined color.

In an embodiment, the display module DM may sense an input applied from the outside. For example, the display module DM may sense a touch of the user as an external input and may display an image corresponding to a sensed signal.

In an embodiment, the display module DM may include an accommodated portion AMP disposed adjacent to the display region DA. The accommodated portion AMP may be disposed adjacent to one of opposite sides of the display module DM disposed opposite to each other in the first direction DR1. The accommodated portion AMP may substantially be the non-display region NDA. The accommodated portion AMP may be defined as the non-display region NDA disposed adjacent to the one side of the display module DM.

In an embodiment, the accommodated portion AMP may have a larger area than the non-display regions NDA disposed adjacent to opposite sides of the display module DM disposed opposite to each other in the second direction DR2 and the non-display region NDA disposed adjacent to the other side of the display module DM that faces in the first direction DR1.

In an embodiment and referring to FIGS. 1 and 4, the display module DM may be a flexible display module. The display module DM may be folded and accommodated in the case CS. The display region DA of the display module DM may be exposed to the outside. The area of the display region DA exposed to the outside may be adjusted depending on the movement of the first case CS1.

In an embodiment, when the display module DM is folded, the accommodated portion AMP may be disposed under the display region DA. The accommodated portion AMP may be accommodated in the case CS and may not be exposed to the outside. A driver for driving elements of the display module DM may be disposed in the accommodated portion AMP.

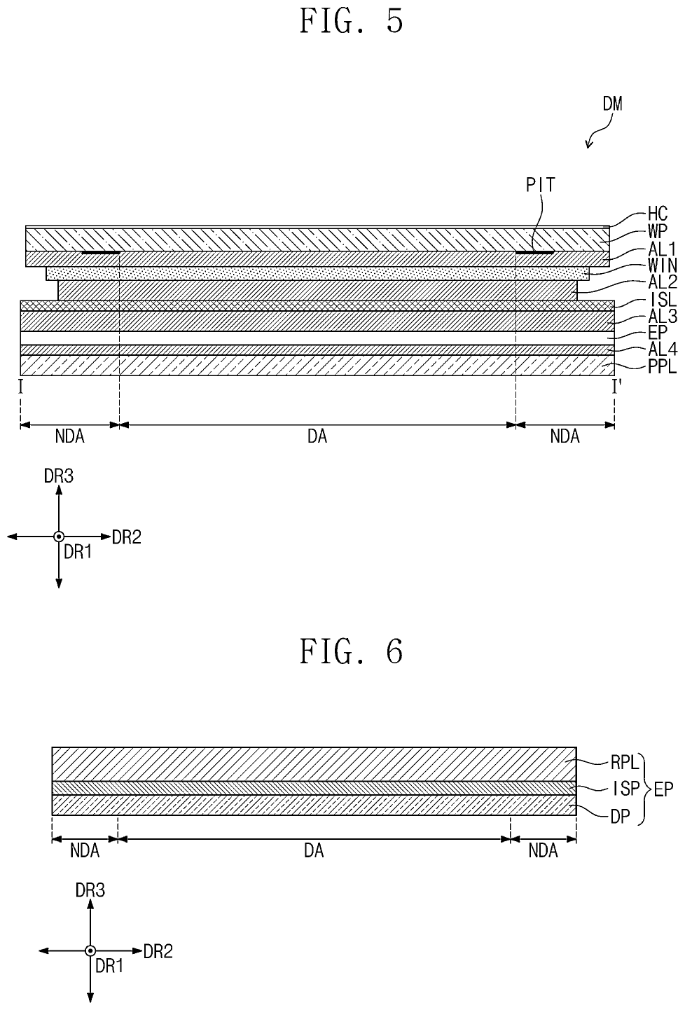

FIG. 5 is a sectional view taken along line I-I′ illustrated in FIG. 3, according to an embodiment.

In an embodiment and referring to FIG. 5, the display module DM may include an electronic panel EP, an impact absorbing layer ISL, a panel protection layer PPL, a window WIN, a window protection layer WP, a hard coating layer HC, and first to fourth adhesive layers AL1 to AL4, respectively.

In an embodiment, the electronic panel EP may display an image. The electronic panel EP may include a display panel, an input sensing unit, and an anti-reflection layer, and the configuration of the electronic panel EP will be described below with reference to FIG. 6.

In an embodiment, the impact absorbing layer ISL may be disposed on the electronic panel EP. The impact absorbing layer ISL may protect the electronic panel EP by absorbing external impact applied from above the display device DD directed toward the electronic panel EP. The impact absorbing layer ISL may be manufactured in the form of a stretchable film.

In an embodiment, the impact absorbing layer ISL may include a flexible plastic material. The flexible plastic material may be defined as a synthetic resin film. For example, the impact absorbing layer ISL may include a flexible plastic material such as polyimide (PI) or polyethylene terephthalate (PET).

In an embodiment, the window WIN may be disposed on the impact absorbing layer ISL. The window WIN may protect the electronic panel EP from external scratches. The window WIN may have a property of being optically clear. The window WIN may include glass. However, without being limited thereto, the window WIN may include a synthetic resin film.

In an embodiment, the window protection layer WP may be disposed on the window WIN. The window protection layer WP may include a flexible plastic material such as polyimide or polyethylene terephthalate. The hard coating layer HC may be disposed on the upper surface of the window protection layer WP.

In an embodiment, a printed layer PIT may be disposed on the lower surface of the window protection layer WP. The printed layer PIT may be black in color. However, the color of the printed layer PIT is not limited thereto. The printed layer PIT may be disposed adjacent to the periphery of the window protection layer WP. The printed layer PIT may overlap the non-display region NDA.

In an embodiment, the panel protection layer PPL may be disposed under the electronic panel EP and may protect a lower portion of the electronic panel EP. The panel protection layer PPL may include a flexible plastic material. For example, the panel protection layer PPL may include polyimide or polyethylene terephthalate.

In an embodiment, the first adhesive layer AL1 may be disposed between the window protection layer WP and the window WIN. The window protection layer WP and the window WIN may be bonded to each other by the first adhesive layer AL1. The first adhesive layer AL1 may cover the printed layer PIT.

In an embodiment, the second adhesive layer AL2 may be disposed between the window WIN and the impact absorbing layer ISL. The window WIN and the impact absorbing layer ISL may be bonded to each other by the second adhesive layer AL2.

In an embodiment, the third adhesive layer AL3 may be disposed between the impact absorbing layer ISL and the electronic panel EP. The impact absorbing layer ISL and the electronic panel EP may be bonded to each other by the third adhesive layer AL3.

In an embodiment, the fourth adhesive layer AL4 may be disposed between the electronic panel EP and the panel protection layer PPL. The electronic panel EP and the panel protection layer PPL may be bonded to each other by the fourth adhesive layer AL4.

In an embodiment, the first to fourth adhesive layers AL1 to AL4, respectively, may include a pressure sensitive adhesive (PSA) or an optically clear adhesive (OCA). However, the type of adhesive is not limited thereto.

FIG. 6 is a sectional view illustrating the configuration of the electronic panel illustrated in FIG. 5, according to an embodiment.

In FIG. 6, a section of the electronic panel EP viewed in the first direction DR1 is illustrated, according to an embodiment.

In an embodiment and referring to FIG. 6, the electronic panel EP may include the display panel DP, the input sensing unit ISP disposed on the display panel DP, and the anti-reflection layer RPL disposed on the input sensing unit ISP. The display panel DP may be a flexible display panel. For example, the display panel DP may include a flexible substrate and a plurality of elements disposed on the flexible substrate.

In an embodiment, the display panel DP may be an emissive display panel, but is not particularly limited. For example, the display panel DP may be an organic light emitting display panel or an inorganic light emitting display panel. An emissive layer of the organic light emitting display panel may include an organic luminescent material. An emissive layer of the inorganic light emitting display panel may include quantum dots, quantum rods, and the like. Hereinafter, it will be exemplified that the display panel DP is an organic light emitting display panel.

In an embodiment, the input sensing unit ISP may include a plurality of sensors (not illustrated) for sensing an external input. For example, the input sensing unit ISP may sense an external input using a capacitance method. However, a sensing method of the input sensing unit ISP is not limited thereto. The input sensing unit ISP may be directly formed on the display panel DP when the electronic panel EP is manufactured.

In an embodiment, the anti-reflection layer RPL may be disposed on the input sensing unit ISP. The anti-reflection layer RPL may be directly formed on the input sensing unit ISP when the electronic panel EP is manufactured. The anti-reflection layer RPL may be defined as a film for preventing reflection of external light. The anti-reflection layer RPL may decrease the reflectance of external light directed incident toward the display panel DP from above the display device DD.

In an embodiment, when external light travelling toward the display panel DP is reflected from the display panel DP and provided back to the user, the user may visually recognize the external light as in a mirror. To prevent such a phenomenon, the anti-reflection layer RPL may include a plurality of color filters that display the same colors as those of pixels of the display panel DP.

In an embodiment, the color filters may filter external light into the same colors as those of the pixels. In this case, the external light may not be visible to the user. However, without being limited thereto, the anti-reflection layer RPL may include a phase retarder and/or a polarizer to decrease the reflectance of the external light.

For example, in an embodiment, the input sensing unit ISP may be directly formed on the display panel DP, and the anti-reflection layer RPL may be directly formed on the input sensing unit ISP. However, embodiments are not limited thereto. For example, the input sensing unit ISP may be separately manufactured and may be attached to the display panel DP by an adhesive layer, and the anti-reflection layer RPL may be separately manufactured and may be attached to the input sensing unit ISP by an adhesive layer.

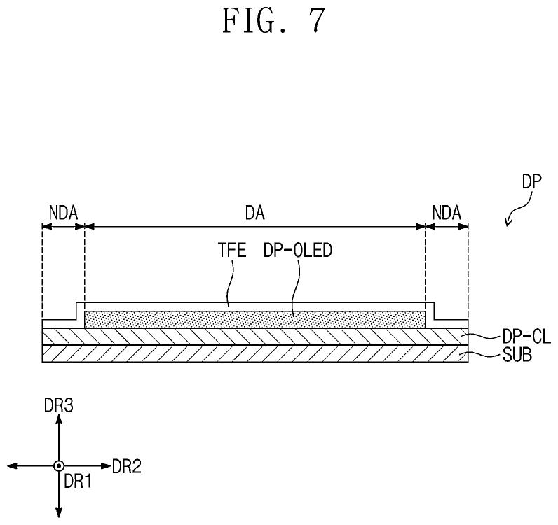

FIG. 7 is a sectional view illustrating a configuration of the display panel illustrated in FIG. 6, according to an embodiment.

In FIG. 7, a section of the display panel DP viewed in the first direction DR1 is illustrated, according to an embodiment.

In an embodiment and referring to FIG. 7, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

In an embodiment, the substrate SUB may include a display region DA and a non-display region NDA disposed around the display region DA. The substrate SUB may include a flexible plastic material such as polyimide. The display element layer DP-OLED may be disposed on the display region DA.

In an embodiment, a plurality of pixels may be disposed in the display region DA. Each of the pixels may include a light emitting element that is connected to transistors disposed in the circuit element layer DP-CL and is disposed in the display element layer DP-OLED.

In an embodiment, the thin film encapsulation layer TFE may be disposed on the circuit element layer DP-CL to cover the display element layer DP-OLED. The thin film encapsulation layer TFE may include inorganic layers and an organic layer between the inorganic layers. The inorganic layers may protect the pixels from moisture/oxygen. The organic layer may protect the pixels from foreign matter such as dust particles.

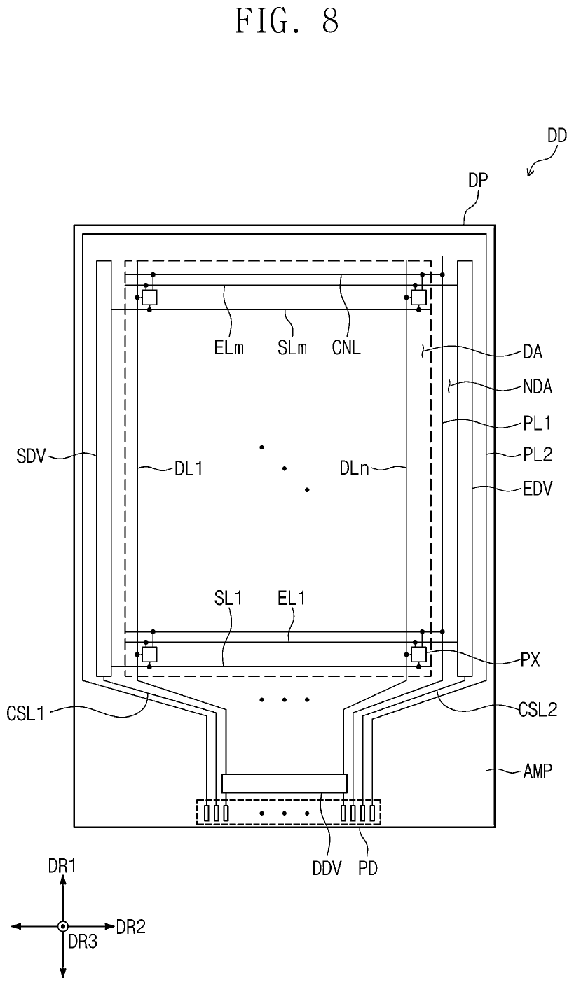

FIG. 8 is a plan view of the display panel illustrated in FIG. 7, according to an embodiment.

In an embodiment and referring to FIG. 8, the display device DD may include the display panel DP, a scan driver SDV, a data driver DDV, a light emission driver EDV, and a plurality of pads PD.

In an embodiment, the display panel DP may have a rectangular shape with long sides extending in the first direction DR1 and short sides extending in the second direction DR2. However, the shape of the display panel DP is not limited thereto. The display panel DP may include a display region DA and a non-display region NDA surrounding the display region DA.

In an embodiment, the display panel DP may include a plurality of pixels PX, a plurality of scan lines SL1 to SLm, a plurality of data lines DL1 to DLn, a plurality of light emission lines EL1 to ELm, first and second control lines CSL1 and CSL2, respectively, first and second power lines PL1 and PL2, respectively, and a plurality of connecting lines CNL. Here, “m” and “n” are natural numbers.

In an embodiment, the pixels PX may be disposed in the display region DA. The scan driver SDV and the light emission driver EDV may be disposed in the non-display regions NDA to be located adjacent to the long sides of the display panel DP. The data driver DDV may be disposed in the non-display region NDA to be located adjacent to one of the short sides of the display panel DP. The data driver DDV may be disposed adjacent to a lower end of the display panel DP when viewed from above the plane.

In an embodiment and referring to FIG. 8, the accommodated portion AMP may be defined as the non-display region NDA disposed adjacent to the lower end of the display panel DP. The data driver DDV may be disposed on the accommodated portion AMP.

In an embodiment, the scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The light emission lines EL1 to ELm may extend in the second direction DR2 and may be connected to the pixels PX and the light emission driver EDV.

In an embodiment, the first power line PL1 may extend in the first direction DR1 and may be disposed in the non-display region NDA. The first power line PL1 may be disposed between the display region DA and the light emission driver EDV.

In an embodiment, the connecting lines CNL may extend in the second direction DR2 and may be arranged in the first direction DR1. The connecting lines CNL may be connected to the first power line PL1 and the pixels PX. A first voltage may be applied to the pixels PX through the first power line PL1 and the connecting lines CNL connected with each other.

In an embodiment, the second power line PL2 may be disposed in the non-display region NDA and may extend along the long sides of the display panel DP and the other short side of the display panel DP where the data driver DDV is not disposed. The second power line PL2 may be disposed outward of the scan driver SDV and the light emission driver EDV.

Although not illustrated, in an embodiment, the second power line PL2 may extend toward the display region DA and may be connected to the pixels PX. A second voltage having a lower level than the first voltage may be applied to the pixels PX through the second power line PL2.

In an embodiment, the first control line CSL1 may be connected to the scan driver SDV and may extend toward the lower end of the display panel DP. The second control line CSL2 may be connected to the light emission driver EDV and may extend toward the lower end of the display panel DP. The data driver DDV may be disposed between the first control line CSL1 and the second control line CSL2.

In an embodiment, the pads PD may be disposed in the non-display region NDA to be located adjacent to the lower end of the display panel DP and may be located closer to the lower end of the display panel DP than the data driver DDV. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Although not illustrated, in an embodiment, the display device DD may further include a timing controller for controlling operations of the scan driver SDV, the data driver DDV, and the light emission driver EDV and a voltage generator for generating the first and second voltages. The timing controller and the voltage generator may be connected to the pads PD through a printed circuit board.

In an embodiment, the scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The light emission driver EDV may generate a plurality of light emission signals, and the light emission signals may be applied to the pixels PX through the light emission lines EL1 to ELm.

In an embodiment, the pixels PX may receive the data voltages in response to the scan signals. The pixels PX may display an image by emitting light having luminance corresponding to the data voltages in response to the light emission signals.

FIG. 9 is a perspective view of the display module illustrated in FIG. 3 and the support part supporting the display module, according to an embodiment.

In an embodiment and referring to FIG. 9, the support plate SPT may be disposed under the display module DM and may support the display module DM. The support part SUP may include a support plate SPT, a plurality of support bars SB, and a plurality of link bars LKB.

In an embodiment, the support plate SPT, the support bars SB, and the link bars LKB may include metal. The support plate SPT, the support bars SB, and the link bars LKB may include a metallic material such as stainless steel or titanium alloy.

In an embodiment, the support plate SPT may be disposed on the lower surface of the display module DM. The support plate SPT may have a plane defined by the first and second directions DR1 and DR2. The support plate SPT may have a rectangular shape extending longer in the first direction DR1 than in the second direction DR2.

In an embodiment, the support plate SPT may include a flat part PLT and a flexible part FLP. The flat part PLT may have a plane defined by the first direction DR1 and the second direction DR2. The flat part PLT may remain flat. The flat part PLT may have a higher elastic modulus than the flexible part FLP.

In an embodiment, the flexible part FLP may have a plurality of openings LOP defined therein. Due to the openings LOP, the flexible part FLP may be more flexible than the flat part PLT. That is, the flexible part FLP may have a lower elastic modulus than the flat part PLT and may be more easily bent than the flat part PLT. The flexible part FLP may be folded and accommodated in the first and second cases CS1 and CS2.

In an embodiment, the support bars SB and the link bars LKB may be disposed under the flexible part FLP. The support bars SB may extend in the second direction DR2 and may be arranged in the first direction DR1. The link bars LKB may be arranged in the first direction DR1. The link bars LKB may be disposed on opposite sides of the support bars SB to be located opposite to each other in the second direction DR2.

In an embodiment, when viewed from above the plane, the openings LOP may be defined in portions of the flexible part FLP that do not overlap the support bars SB. However, without being limited thereto, the openings LOP may be defined in portions of the flexible part FLP that overlap the support bars SB. The portions of the flexible part FLP in which the openings LOP are defined may be defined as a lattice pattern.

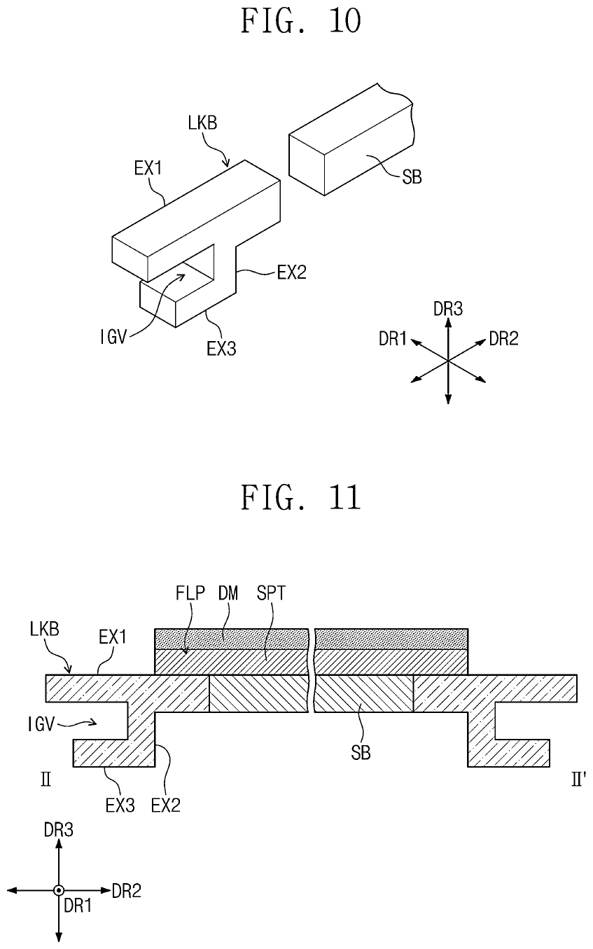

FIG. 10 is an enlarged view illustrating a portion of one of the support bars illustrated in FIG. 9 and a link bar disposed adjacent to the support bar, according to an embodiment.

In FIG. 10, the link bar LKB and the support bar SB are illustrated in a state of being separated from each other, according to an embodiment.

In an embodiment and referring to FIG. 10, the link bar LKB may include a first extension EX1, a second extension EX2, and a third extension EX3. The first extension EX1 may extend in the second direction DR2. The second extension EX2 may extend downward from a portion of the first extension EX1. The third extension EX3 may extend from a lower end of the second extension EX2 in the second direction DR2 and may face the first extension EX1 in the third direction DR3.

In an embodiment, a space between the first, second, and third extensions EX1, EX2, and EX3, respectively, may be defined as an insertion groove IGV. The insertion groove IGV may be defined on one side of the link bar LKB that does not face the support bar SB. A function of the insertion groove IGV will be described below in detail.

FIG. 11 is a sectional view taken along line II-II′ illustrated in FIG. 9, according to an embodiment.

In an embodiment and referring to FIGS. 9 and 11, the support bars SB may be connected to the support plate SPT. For example, the support bars SB may be connected to the lower surface of the flexible part FLP of the support plate SPT by a welding process.

In an embodiment, the link bars LKB may be connected to the opposite sides of the support bars SB to be located opposite to each other in the second direction DR2. For example, the link bars LKB may be connected to the opposite sides of the support bars SB by a welding process. Portions of the first extensions EX1 disposed inward of the second extensions EX2 may be disposed under the flexible part FLP and may be connected to the opposite sides of the support bars SB.

In an embodiment, the link bars LKB may be connected to the opposite sides of the support bars SB and may extend to the outside. The link bars LKB may protrude outwardly from opposite sides of the support plate SPT to be located opposite to each other in the second direction DR2. The insertion grooves IGV defined in the link bars LKB may be defined to face toward the outside. The insertion grooves IGV may be defined outward of the support plate SPT and the display module DM.

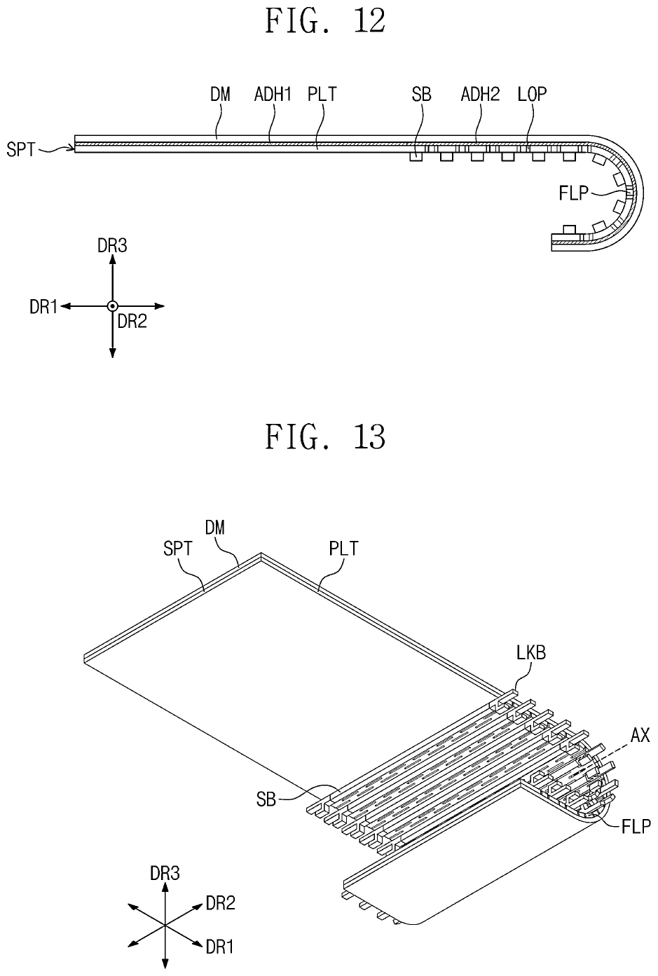

In an embodiment, the display module DM may be disposed on the support plate SPT. The display module DM may be coupled with the support plate SPT by an adhesive layer (illustrated in FIG. 12).

FIG. 12 is a view illustrating a configuration in which the display module and the support plate illustrated in FIG. 9 are bonded to each other, according to an embodiment.

In an embodiment and referring to FIG. 12, side surfaces of the display module DM and the support plate SPT viewed in the second direction DR2 are illustrated. Furthermore, the support bars SB are illustrated together with the support plate SPT, and the link bars LKB are omitted.

In an embodiment and referring to FIG. 12, the support plate SPT may be disposed under the display module DM and may be attached to the display module DM. The support plate SPT may be attached to the rear surface of the display module DM to be opposite to the front surface (e.g., the display surface) of the display module DM.

In an embodiment, adhesive layers ADH1 and ADH2 may be disposed between the support plate SPT and the display module DM. The support plate SPT and the display module DM may be bonded to each other by the adhesive layers ADH1 and ADH2. For example, the adhesive layers ADH1 and ADH2 may be pressure sensitive adhesive layers.

In an embodiment, the adhesive layers ADH1 and ADH2 may include the first adhesive layer ADH1 disposed between the display module DM and the flat part PLT and the second adhesive layer ADH2 disposed between the display module DM and the flexible part FLP. The first adhesive layer ADH1 may be disposed under the portion of the display module DM that overlaps the flat part PLT, and the second adhesive layer ADH2 may be disposed under the portion of the display module DM that overlaps the flexible part FLP.

In an embodiment, the flat part PLT may be attached to the display module DM by the first adhesive layer ADH1, and the flexible part FLP may be attached to the display module DM by the second adhesive layer ADH2. The flexible part FLP and the portion of the display module DM that overlaps the flexible part FLP may be folded, and the support plate SPT and the display module DM may be accommodated in the above-described case CS.

In an embodiment, the second adhesive layer ADH2 may have a modulus different from that of the first adhesive layer ADH1. For example, the second adhesive layer ADH2 may have a lower storage modulus than the first adhesive layer ADH1. That is, the second adhesive layer ADH2 may be more flexible than the first adhesive layer ADH1.

In an embodiment, the flexible part FLP, which is more flexible than the flat part PLT, may be folded together with the display module DM. When viewed from above the plane, the openings LOP defined in the flexible part FLP may be disposed between the support bars SB. The openings LOP may not overlap the support bars SB. Due to the openings LOP, the flexible part FLP may be more easily folded.

In an embodiment, the second adhesive layer ADH2 attached to the flexible part FLP may have a low storage modulus such that the flexible part FLP is easily folded together with the display module DM. Since the flat part PLT remains flat, the first adhesive layer ADH1 having a high storage modulus may be attached to the flat part PLT such that the flat part PLT is not easily bent.

Hereinafter, in the drawings, the first and second adhesive layers ADH1 and ADH2 that attach the display module DM to the support plate SPT are omitted.

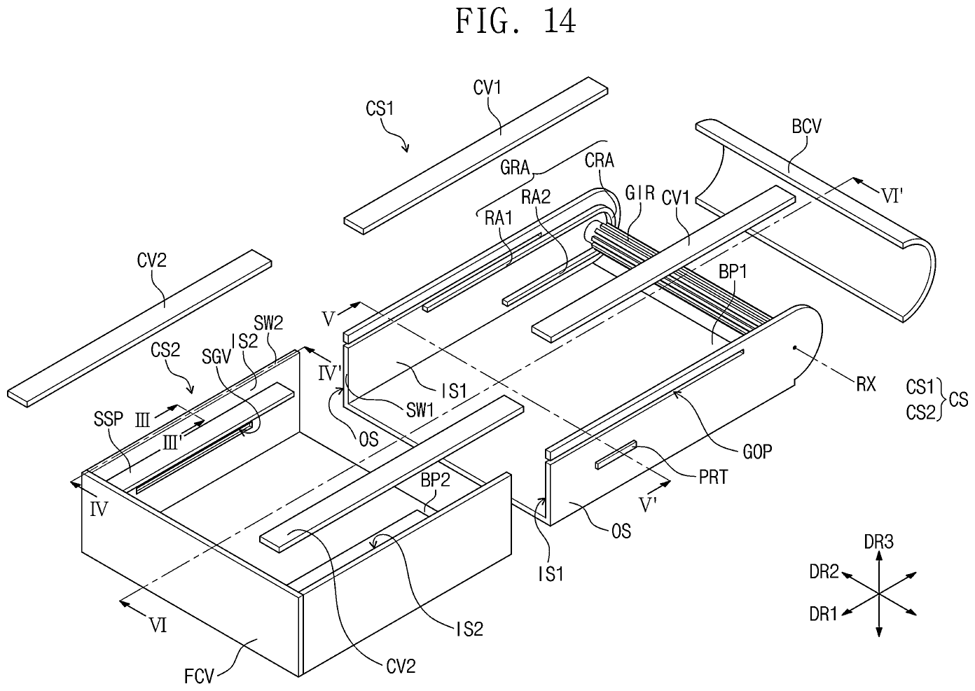

FIG. 13 is a view illustrating a folded state of the display module and the support plate in the state in which the display module, the support plate, the support bars, and the link bars illustrated in FIG. 9 are coupled, according to an embodiment.

In FIG. 13, the lower surface of the support plate SPT is illustrated such that the support bars SB and the link bars LKB are more easily illustrated.

In an embodiment and referring to FIG. 13, the support plate SPT, the support bars SB, and the link bars LKB may be coupled together by welding as described with reference to FIG. 11. Furthermore, as described with reference to FIG. 12, the display module DM may be attached to the support plate SPT by the first and second adhesive layers ADH1 and ADH2.

In an embodiment, the flat part PLT may remain flat and may support the portion of the display module DM disposed on the flat part PLT. The portion of the display module DM that overlaps the flat part PLT may be maintained in a flat state by the flat part PLT.

In an embodiment, the flexible part FLP may extend from the flat part PLT in the first direction DR1 and thereafter may be folded about an axis AX extending in the second direction DR2. The portion of the display module DM disposed on the flexible part FLP may be folded about the axis AX together with the flexible part FLP. The axis AX may be a rotational axis of a gear that will be described below, and this configuration will be described below in detail.

In an embodiment, as the flexible part FLP is folded, the support bars SB and the link bars LKB may be arranged depending on the folded shape of the flexible part FLP.

FIG. 14 is an exploded perspective view of the case illustrated in FIG. 1, according to an embodiment.

In an embodiment and referring to FIG. 14, the case CS may include the first case CS1 and the second case CS2 that are disposed in the first direction DR1. The first case CS1 and the second case CS2 may be coupled with each other in the first direction DR1.

In an embodiment, the first case CS1 may include a first bottom part BP1, a plurality of first sidewalls SW1, a plurality of first covers CV1, a rear part BCV, a plurality of protrusions PRT, and a plurality of guide rails GRA. The display device DD may further include a gear GIR disposed in the first case CS1.

In an embodiment, the first bottom part BP1 may have a plane defined by the first and second directions DR1 and DR2. The first sidewalls SW1 may extend upward (e.g., in the upward direction based on the third direction DR3) from opposite sides of the first bottom part BP1 to be located opposite to each other in the second direction DR2. The first sidewalls SW1 may have a plane defined by the first and third directions DR1 and DR3. The first sidewalls SW1 may extend longer in the first direction DR1 than in the third direction DR3.

In an embodiment, one side of opposite sides of each of the first sidewalls SW1 disposed opposite to each other in the first direction DR1 may have a curved shape that is convex toward the outside. The other side of the opposite sides of each of the first sidewalls SW1 disposed opposite to each other in the first direction DR1 may have a straight-line shape that extends in the third direction DR3.

In an embodiment, the first covers CV1 may be disposed on the first sidewalls SW1. The first covers CV1 may be connected to the upper surfaces of the first sidewalls SW1. The first covers CV1 may have a plane defined by the first and second directions DR1 and DR2. The first covers CV1 may extend longer in the first direction DR1 than in the second direction DR2.

In an embodiment, the rear part BCV may be disposed on one side of the opposite sides of the first bottom part BP1 disposed opposite to each other in the first direction DR1 and the one side of opposite sides of each of the first sidewalls SW1 disposed opposite to each other in the first direction DR1. The rear part BCV may be connected to the one side of the first bottom part BP1 and the one side of each of the first sidewalls SW1. The one side of each of the first sidewalls SW1 may be disposed adjacent to the one side of the first bottom part BP1.

In an embodiment, the rear part BCV may have a shape that is convex toward the outside to correspond to the curved shape on the one side of each of the first sidewalls SW1. For example, when viewed in the second direction DR2, the outer surface of the rear part BCV that faces toward the outside may have a curved shape convex toward the outside.

In an embodiment, surfaces of the first sidewalls SW1 that face each other in the second direction DR2 may be defined as first inner surfaces IS1. Surfaces of the first sidewalls SW1 opposite to the first inner surfaces IS1 may be defined as outer surfaces OS. The first inner surfaces IS1 may define inner surfaces of the case CS that face each other in the second direction DR2. Specifically, the first inner surfaces IS1 may define inner surfaces of the first case CS1 that face each other in the second direction DR2.

In an embodiment, the protrusions PRT may be disposed on the outer surfaces OS, respectively. The protrusions PRT may extend in the first direction DR1. The protrusions PRT may protrude from the outer surfaces OS.

In an embodiment, the guide rails GRA may be disposed on the first inner surfaces IS1. The guide rails GRA may be disposed adjacent to the rear part BCV. The guide rails GRA may be connected to the first inner surfaces IS1.

In an embodiment, each of the guide rails GRA may include a first rail RA1, a second rail RA2, and a curved rail CRA. The first rail RA1 may extend in the first direction DR1. The second rail RA2 may be disposed under the first rail RA1 and may extend in the first direction DR1. The first rail RA1 may be longer than the second rail RA2.

In an embodiment, the curved rail CRA may extend from one side of the first rail RA1 to one side of the second rail RA2. The one side of the first rail RA1 and the one side of the second rail RA2 may be disposed adjacent to the rear part BCV. The curved rail CRA may be disposed adjacent to the rear part BCV and may have a curved shape convexly extending toward the rear part BCV.

In an embodiment, the second case CS2 may include a second bottom part BP2, a front part FCV, a plurality of second sidewalls SW2, a plurality of second covers CV2, and a plurality of sub-support parts SSP. The second bottom part BP2 may have a plane defined by the first and second directions DR1 and DR2.

In an embodiment, the second sidewalls SW2 may extend upward from opposite sides of the second bottom part BP2 disposed opposite to each other in the second direction DR2. The second sidewalls SW2 may have a plane defined by the first and third directions DR1 and DR3. The second sidewalls SW2 may extend longer in the first direction DR1 than in the third direction DR3.

In an embodiment, the second bottom part BP2 may be disposed under the first bottom part BP1. The second sidewalls SW2 may be disposed outward of the first sidewalls SW1. That is, the second sidewalls SW2 may be disposed on the outer surfaces OS of the first sidewalls SW1.

In an embodiment, the front part FCV may be disposed to face the rear part BCV. The front part FCV may be disposed on one side of opposite sides of the second bottom part BP2 to be located opposite to each other in the first direction DR1. The one side of the second bottom part BP2 may be defined as a portion of the second bottom part BP2 that is furthest from the rear part BCV. The front part FCV may be connected to the one side of the second bottom part BP2 and may extend upward.

In an embodiment, the front part FCV may have a plane defined by the second and third directions DR2 and DR3. The front part FCV may extend longer in the second direction DR2 than in the third direction DR3.

In an embodiment, surfaces of the second sidewalls SW2 that face each other in the second direction DR2 may be defined as second inner surfaces IS2. Sliding grooves SGV may be defined on the second inner surfaces IS2. The sliding grooves SGV may extend in the first direction DR1. When the second case CS2 is coupled to the first case CS1 and the second sidewalls SW2 are disposed on the outer surfaces OS of the first sidewalls SW1, the protrusions PRT may be inserted into the sliding grooves SGV. This configuration will be described below in detail.

In an embodiment, the gear GIR may have a cylindrical shape extending in the second direction DR2. A plurality of protrusions that extend in the second direction DR2 and that are arranged along the outer circumferential surface of the gear GIR may be disposed on the outer circumferential surface of the gear GIR. The protrusions of the gear GIR may be spaced apart from the first sidewalls SW1.

In an embodiment, the gear GIR may be connected to the first sidewalls SW1. Opposite sides of the gear GIR disposed to be opposite to each other in the second direction DR2 may be connected to the first sidewalls SW1. The gear GIR may rotate about a rotational axis RX extending in the second direction DR2. The rotational axis RX may be the axis AX described above. The gear GIR may be disposed between the first rail RA1 and the second rail RA2. The gear GIR may be disposed adjacent to the curved rail CRA.

In an embodiment, the second covers CV2 may be disposed on the second sidewalls SW2. The second covers CV2 may be connected to the upper surfaces of the second sidewalls SW2. The second covers CV2 may have a plane defined by the first and second directions DR1 and DR2. The second covers CV2 may extend longer in the first direction DR1 than in the second direction DR2. When the first case CS1 and the second case CS2 are coupled with each other, the second covers CV2 may be disposed on the first covers CV1.

In an embodiment, the sub-support parts SSP may be disposed on the second inner surfaces IS2. The sub-support parts SSP may have a plane defined by the first and second directions DR1 and DR2. The sub-support parts SSP may extend longer in the first direction DR1 than in the second direction DR2. The sub-support parts SSP may be disposed adjacent to the front part FCV. The sub-support parts SSP may be connected to the second inner surfaces IS2. The sub-support parts SSP may be disposed above the sliding grooves SGV.

In an embodiment, guide openings GOP may be defined in the first sidewalls SW1. Each of the guide openings GOP may be defined in the corresponding first sidewall SW1 by extending in the first direction DR1 from the opposite side of the corresponding first sidewall SW1. The guide openings GOP may be defined above the guide rails GRA. For example, the guide openings GOP may be defined above the first rails RA1.

In an embodiment, the guide openings GOP may overlap the first rails RA1. The guide openings GOP may extend so as to be located adjacent to the curved rails CRA. The first rails RA1 may extend to be closer to the first sidewalls SW1 than the second rails RA2.

In an embodiment, the first rails RA1 may extend below the guide openings GOP. When the first case CS1 and the second case CS2 are coupled with each other, the sub-support parts SSP may be disposed in the guide openings GOP.

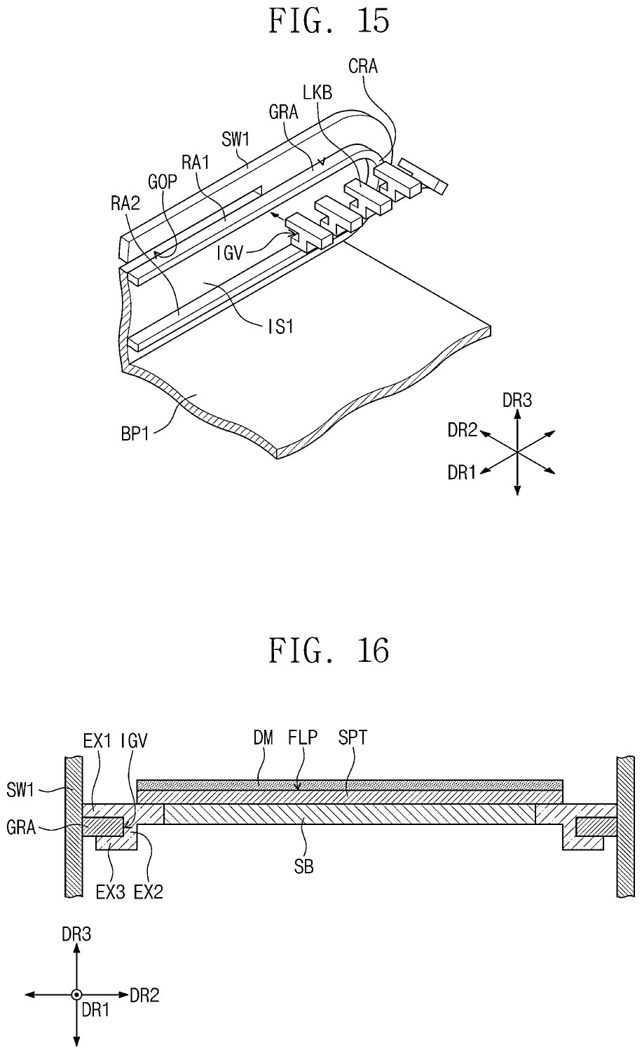

FIG. 15 is a view for explaining a configuration in which the link bars illustrated in FIGS. 9, 10, 11, and 13 are coupled to the guide rail, according to an embodiment. FIG. 16 is a sectional view illustrating the state in which the link bars illustrated in FIG. 15 are coupled to the guide rail, according to an embodiment.

In an embodiment and referring to FIG. 15, some of the link bars LKB coupled to the guide rail GRA connected to one first inner surface IS1 are illustrated. FIG. 16 illustrates a section corresponding to FIG. 11, and sections of the link bars LKB coupled to the guide rails GRA connected to the first inner surfaces IS1 are illustrated in FIG. 16.

In an embodiment and referring to FIGS. 15 and 16, the guide rails GRA may be connected to the first sidewalls SW1. The link bars LKB may be coupled to the guide rails GRA. For example, the guide rails GRA may be disposed in the insertion grooves IGV defined on the sides of the link bars LKB. The guide rails GRA may be inserted into the insertion grooves IGV and may be disposed in the insertion grooves IGV.

In an embodiment, the link bars LKB may move along the guide rails GRA. The link bars LKB may move in the extension direction of the guide rails GRA through the insertion grooves IGV. The support bars SB may be coupled to the guide rails GRA through the link bars LKB and may move together with the link bars LKB.

In an embodiment, the support plate SPT may be coupled to the guide rails GRA by the link bars LKB and the support bars SB. The support plate SPT may move depending on the movement of the link bars LKB and the support bars SB.

FIG. 17 is a view illustrating a state in which the flat part illustrated in FIG. 9 is disposed on the sub-support part illustrated in FIG. 14, according to an embodiment.

In an embodiment and referring to FIG. 17, a portion of the second sidewall SW2, a portion of the second bottom part BP2, a portion of the flat part PLT, and the sub-support part SSP are illustrated, and the support plate SPT is illustrated by dotted lines.

In an embodiment and referring to FIG. 17, the flexible part FLP of the support plate SPT may be coupled to the guide rails GRA through the link bars LKB. However, the flat part PLT may not be coupled to the guide rails GRA. Accordingly, a structure for supporting the flat part PLT is required. In an embodiment, the sub-support part SSP may be disposed under the flat part PLT and may support the flat part PLT.

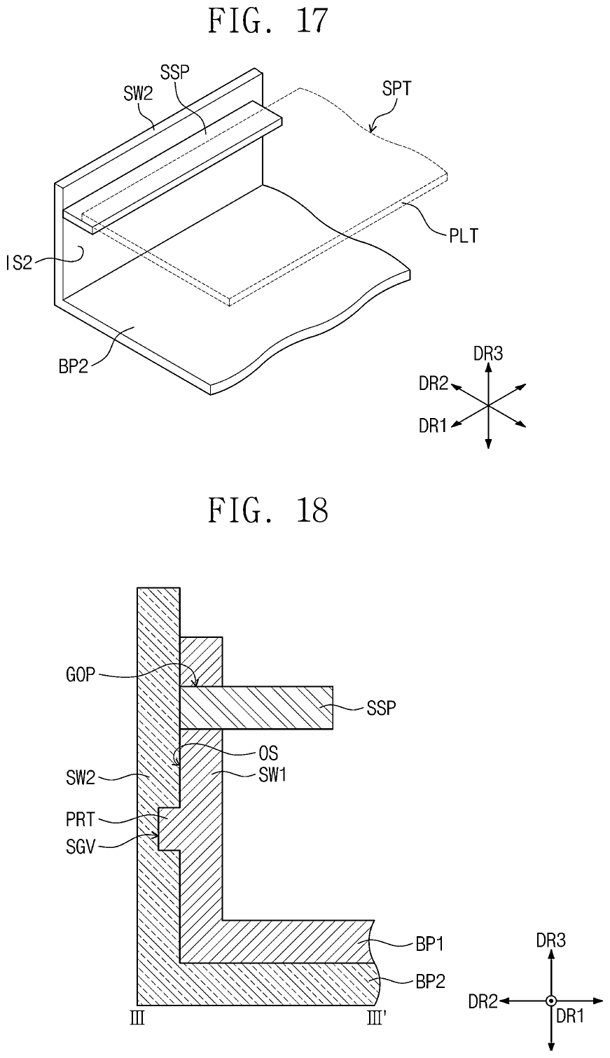

FIG. 18 is a sectional view taken along line III-III′ illustrated in FIG. 14, according to an embodiment.

In an embodiment, assuming that the first and second cases CS1 and CS2 are coupled with each other, the first sidewall SW1 and the second sidewall SW2 are illustrated together in FIG. 18.

In an embodiment and referring to FIGS. 14 and 18, the second bottom part BP2 may be disposed under the first bottom part BP1 when the first and second cases CS1 and CS2 are coupled with each other. The second bottom part BP2 may make contact with the lower surface of the first bottom part BP1. The second sidewall SW2 may be disposed outward of the first sidewall SW1. The second sidewall SW2 may be disposed to make contact with the outer surface OS of the first sidewall SW1.

In an embodiment, the protrusion PRT may protrude from the first sidewall SW1. When the first and second cases CS1 and CS2 are coupled with each other, the protrusion PRT may be disposed in the sliding groove SGV defined on the second sidewall SW2.

In an embodiment, the sub-support part SSP may be connected to the second sidewall SW2. The sub-support part SSP may be disposed in the guide opening GOP defined in the first sidewall SW1. When the first and second cases CS1 and CS2 move relative to each other in the first direction DR1, the sub-support part SSP may move along the guide opening GOP in the first direction DR1.

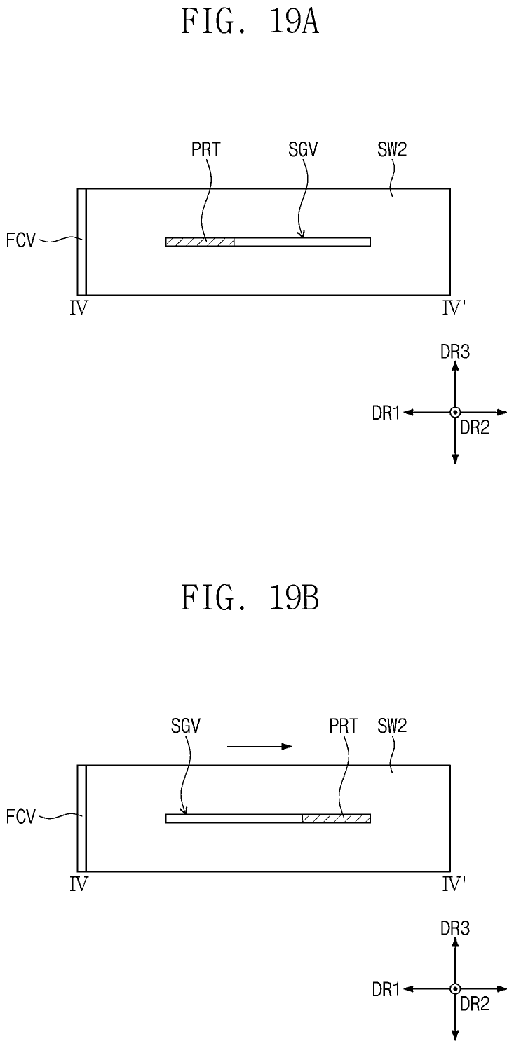

FIGS. 19A and 19B are sectional views taken along line IV-IV′ illustrated in FIG. 14, according to an embodiment.

FIGS. 19A and 19B illustrate a state in which the protrusion PRT is disposed in the sliding groove SGV, according to an embodiment.

In an embodiment and referring to FIGS. 1, 14, 18, and 19A, in the default mode, the protrusion PRT may be disposed on one side of the sliding groove SGV. The one side of the sliding groove SGV may be disposed adjacent to the front part FCV in the first direction DR1. When the first case CS1 moves toward the second case CS2 to a maximum, the protrusion PRT may be disposed on the one side of the sliding groove SGV.

In an embodiment and referring to FIGS. 2, 14, 18, and 19B, when in the extended mode, the first case CS1 may move away from the second case CS2 in the first direction DR1. For example, when the first case CS1 moves in the first direction DR1, the protrusion PRT may move along the sliding groove SGV in the first direction DR1. When the protrusion PRT moves along the sliding groove SGV and is disposed on an opposite side of the sliding groove SGV, the protrusion PRT may stop.

In an embodiment, the opposite side of the sliding groove SGV may be a portion of the sliding groove SGV that is furthest from the front part FCV. The one side and the opposite side of the sliding groove SGV may be disposed opposite to each other in the first direction DR1.

In an embodiment, when the first case CS1 continues to move away from the second case CS2, the first case CS1 may be separated from the second case CS2. However, in an embodiment, the first case CS1 may stop since the protrusion PRT moving in the first direction DR1 is disposed on the opposite side of the sliding groove SGV. The amount of movement of the first case CS1 may be controlled depending on the lengths of the protrusion PRT and the sliding groove SGV in the first direction DR1.

In an embodiment, in the default mode illustrated in FIG. 1 and the extended mode illustrated in FIG. 2, the amount of movement of the first case CS1 relative to the second case CS2 may be determined by the protrusion PRT moving along the sliding groove SGV in the first direction DR1.

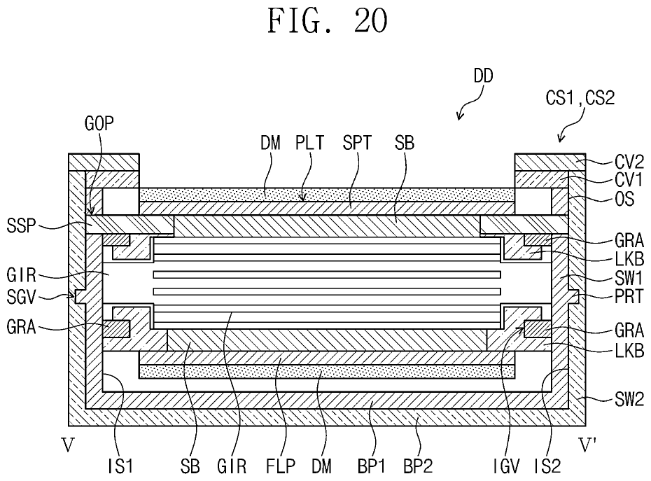

FIG. 20 is a sectional view taken along line V-V′ illustrated in FIG. 14, according to an embodiment.

In an embodiment, in FIG. 20, the support plate SPT and the display module DM accommodated in the first case CS1 are illustrated together with the first case CS1, and the first case CS1 and the second case CS2 are illustrated in a coupled state.

In an embodiment and referring to FIGS. 14, 16, and 20, the guide rails GRA disposed on the first inner surfaces IS1 may face each other in the second direction DR2. The sub-support parts SSP connected to the second inner surfaces IS2 may face each other in the second direction DR2. The link bars LKB may be coupled to the guide rails GRA. The flat part PLT may be disposed on the sub-support parts SSP.

In an embodiment, the support plate SPT supporting the display module DM may be coupled to the guide rails GRA by the support bars SB and the link bars LKB. Furthermore, the flat part PLT may be supported by the sub-support parts SSP. Accordingly, the support plate SPT may easily support the display module DM.

In an embodiment, the first covers CV1 may be disposed on the first sidewalls SW1. The first covers CV1 may extend in the second direction DR2 on the first sidewalls SW1. The first covers CV1, when viewed from above the plane, may be disposed to overlap the link bars LKB protruding outward from the support plate SPT. Since the first covers CV1 cover the link bars LKB, the link bars LKB may not be visible from the outside.

In an embodiment, the second covers CV2 may be disposed on the second sidewalls SW2 and the first covers CV1. When viewed from above the plane, the second covers CV2 may be disposed to overlap the link bars LKB. Since the second covers CV2 cover the link bars LKB, the link bars LKB may not be visible from the outside.

In an embodiment, the display module DM may be exposed to the outside through the opening OP defined between the first covers CV1 and between the second covers CV2.

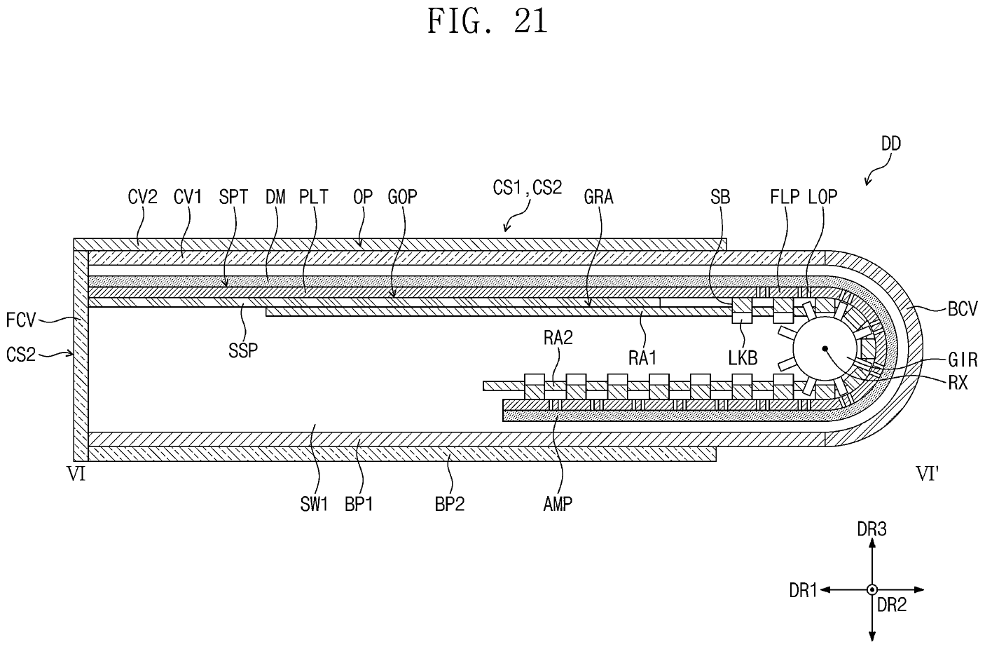

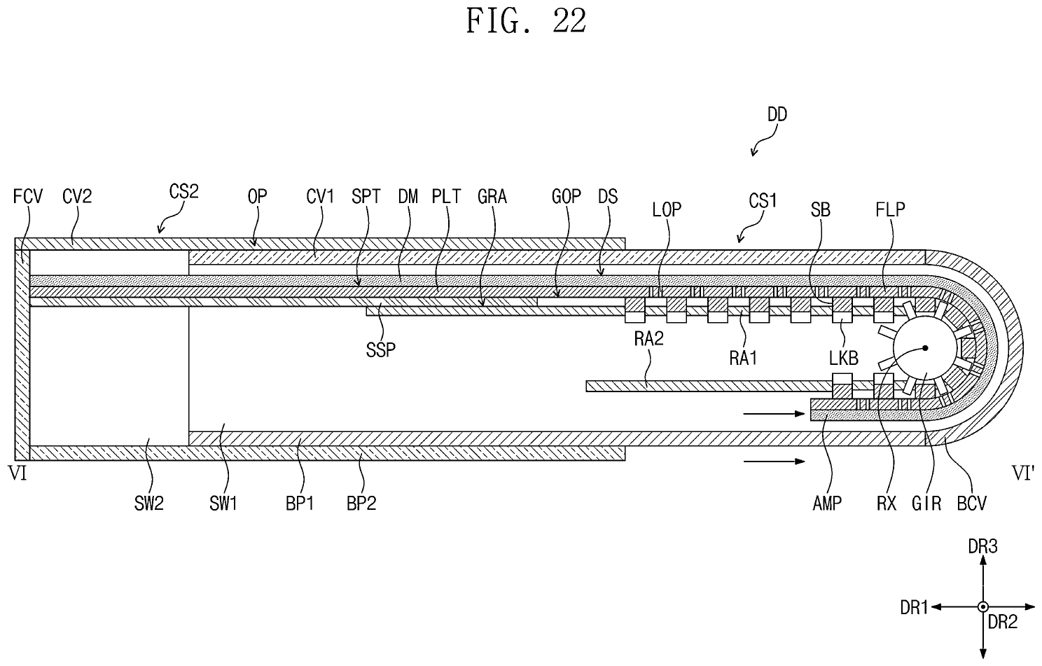

FIG. 21 is a sectional view taken along line VI-VI′ illustrated in FIG. 14, where FIG. 21 illustrates the default mode of the display device illustrated in FIG. 1, according to an embodiment. FIG. 22 is a sectional view taken along line VI-VI′ illustrated in FIG. 14, where FIG. 22 illustrates the extended mode of the display device illustrated in FIG. 2, according to an embodiment.

In FIGS. 21 and 22, the display module DM and the support plate SPT accommodated in the case CS are illustrated together with the case CS, according to an embodiment.

In an embodiment and referring to FIGS. 1 and 21, the display module DM may be disposed on the support plate SPT. The support plate SPT may be folded and accommodated in the case CS. The flat part PLT may support the display module DM. The flexible part FLP may be easily bent together with the display module DM.

In an embodiment, the flat part PLT may be disposed on the sub-support parts SSP, and the flexible part FLP may be folded and coupled to the guide rails GRA. The link bars LKB may be arranged in the shape of the guide rails GRA and may be coupled to the guide rails GRA, and thus the flexible part FLP may also be disposed in the shape of the guide rails GRA. The flexible part FLP, which is more flexible than the flat part PLT, may be more easily bent and disposed along the guide rails GRA.

In an embodiment, the gear GIR may be disposed to be engaged with the support bars SB located adjacent to the gear GIR. For example, the protrusions of the gear GIR may be disposed between the support bars SB to be located adjacent to the gear GIR. The gear GIR may rotate about the rotational axis RX and may move the support bars SB. Although not illustrated, an actuator for rotating the gear GIR may be disposed in the case CS.

In an embodiment, the display module DM and the support plate SPT may be accommodated in the first case CS1 and may be connected to the second case CS2. For example, one side of the display module DM and one side of the support plate SPT may be connected to the front part FCV. The display module DM and the support plate SPT may be connected and fixed to the front part FCV. Accordingly, the display module DM and the support plate SPT connected to the front part FCV may move as the front part FCV moves.

In an embodiment, the accommodated portion AMP of the display module DM described above may be disposed adjacent to an opposite side of the support plate SPT located opposite to the one side of the support plate SPT. Accordingly, the accommodated portion AMP may be disposed in the first case CS1 and may not be exposed to the outside.

According to an embodiment, in the default mode, the sub-support parts SSP may be disposed in the guide openings GOP. Ends of the first rails RA1 may be disposed under the sub-support parts SSP. Ends of the sub-support parts SSP may be disposed adjacent to the support bar SB and the link bars LKB that are foremost on the first rail RA1.

In an embodiment and referring to FIGS. 2 and 22, in the extended mode, the first case CS1 may move away from the second case CS2 in the first direction DR1. Accordingly, the display module DM and the support plate SPT may be extended to the outside. In the extended mode, the gear GIR may rotate about the rotational axis RX in the counterclockwise direction.

In an embodiment, the link bars LKB may move along the guide rails GRA. The flexible part FLP may move along the guide rails GRA depending on the movement of the link bars LKB. As the flexible part FLP moves in the first direction DR1, a portion of the flexible part FLP may be disposed flat.

In an embodiment, the sub-support parts SSP may move relative to the first case CS1 in the first direction DR1. The sub-support parts SSP may be disposed in the guide openings GOP and may move in the first direction DR1 along the guide openings GOP. The ends of the first rails RA1 may be disposed under the guide openings GOP.

In an embodiment, in the extended mode, the sub-support parts SSP may support the flat part PLT and the display module DM on the flat part PLT. Furthermore, in the extended mode, the display module DM on the flexible part FLP disposed flat may be supported by the link bars LKB which are horizontally arranged in the first direction DR1. Accordingly, in the extended mode, the display module DM may be easily supported by the sub-support parts SSP and the support bars SB located adjacent to each other. In the extended mode, some of the support bars SB may be disposed to overlap the guide openings GOP.

In an embodiment, as the area of the display module DM exposed to the outside in the extended mode is extended, the area of the display surface DS exposed to the outside may be extended. When the display device DD is changed from the extended mode to the default mode, the front part FCV and the first case CS1 illustrated in FIG. 22 move toward each other in the first direction DR1. Accordingly, the default mode illustrated in FIG. 21 may be achieved. When the default mode is being achieved, the gear GIR may rotate about the rotational axis RX in the clockwise direction.

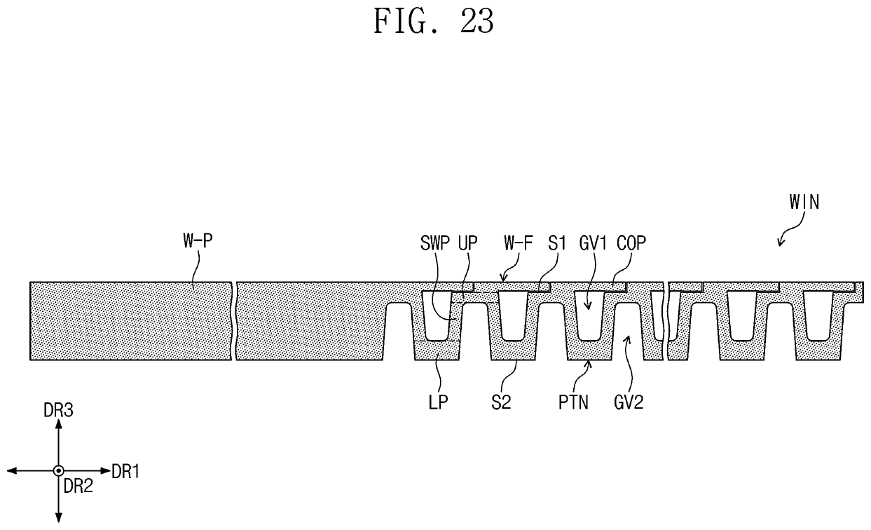

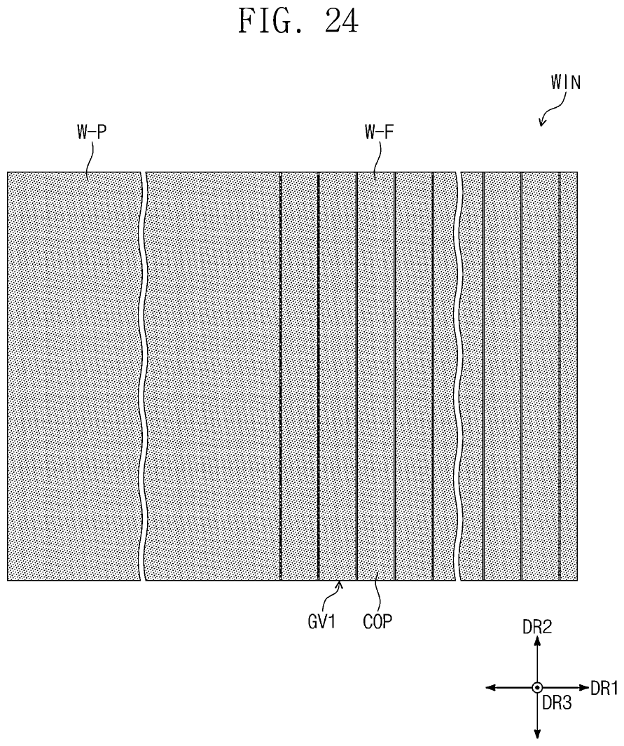

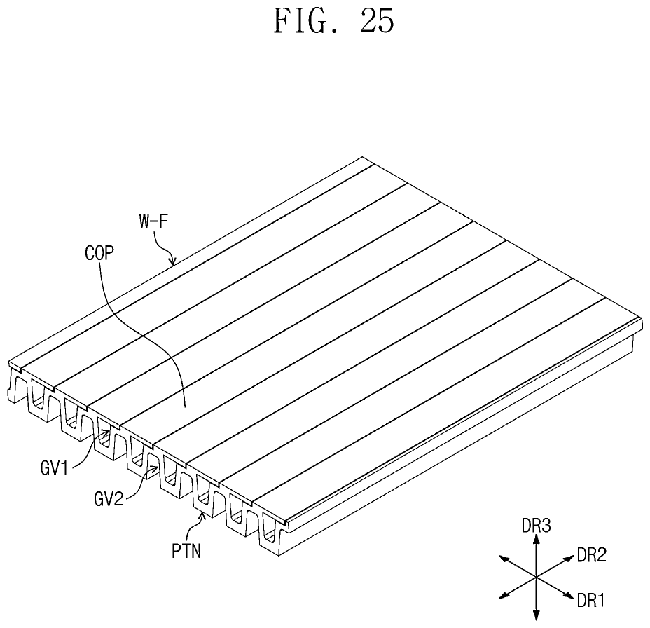

FIG. 23 is a side view of the window illustrated in FIG. 5 as viewed in the second direction, according to an embodiment. FIG. 24 is a plan view of the window illustrated in FIG. 23 as viewed from above, according to an embodiment. FIG. 25 is a perspective view of a flexible window part illustrated in FIG. 23, according to an embodiment.

In an embodiment and referring to FIGS. 23, 24, and 25, the window WIN may include a flat window part W-P and the flexible window part W-F extending from the flat window part W-P in the first direction DR1. The flat window part W-P may correspond to the above-described flat part PLT of the support plate SPT, and the flexible window part W-F may correspond to the above-described flexible part FLP of the support plate SPT.

In an embodiment, the flexible window part W-F may include a pattern part PTN and a plurality of covers COP. The pattern part PTN may include a first surface S1 and a second surface S2 disposed opposite to the first surface S1. Since the window WIN is disposed on the display panel DP as illustrated in FIG. 5, the second surface S2 may be a surface that faces the display panel DP.

In an embodiment, a plurality of first grooves GV1 may be defined on the first surface S1 of the pattern part PTN. The first grooves GV1 may be defined to be recessed from the first surface S1 toward the second surface S2. The first grooves GV1 may be arranged in the first direction DR1 and may extend in the second direction DR2.

In an embodiment, a plurality of second grooves GV2 may be defined on the second surface S2 of the pattern part PTN. The second grooves GV2 may be defined to be recessed from the second surface S2 toward the first surface S1. The second grooves GV2 may be arranged in the first direction DR1 and may extend in the second direction DR2. The first direction DR1 may be defined as one direction.

In an embodiment, the first grooves GV1 and the second grooves GV2 may alternate with one another in the first direction DR1. The first grooves GV1 and the second grooves GV2 may be arranged to be disposed adjacent to one another in the first direction DR1. For example, in FIG. 23, the second groove GV2 is defined first from the flat window part W-P. However, without being limited thereto, in an embodiment, the first groove GV1 may be defined first from the flat window part W-P.

In an embodiment, although the first grooves GV1 and the second grooves GV2 are not defined on the flat window part W-P, the first grooves GV1 and the second grooves GV2 may be defined on the flexible window part W-F. Due to the first grooves GV1 and the second grooves GV2, the flexible window part W-F may be more flexible than the flat window part W-P.

In an embodiment, depending on this structure, the flat window part W-P may have a higher elastic modulus than the flexible window part W-F. The flexible window part W-F may have a lower elastic modulus than the flat window part W-P and may be more easily bent than the flat window part W-P. The flexible window part W-F may be easily folded like the flexible part FLP of the support plate SPT described above.

In an embodiment, the covers COP may be disposed above the first grooves GV1 and may cover the first grooves GV1, respectively. As illustrated in FIG. 24, the covers COP, when viewed from above the plane, may extend in the second direction DR2 and may be arranged in the first direction DR1.

In an embodiment and referring to FIG. 23, the pattern part PTN may include a plurality of lower end portions LP, a plurality of upper end portions UP, and a plurality of sidewall portions SWP. The lower end portions LP may be defined as portions of the pattern part PTN disposed below the first grooves GV1. The upper end portions UP may be defined as portions of the pattern part PTN disposed above the second grooves GV2.

In an embodiment, the sidewall portions SWP may be defined as portions of the pattern part PTN disposed between the first and second grooves GV1 and GV2, respectively. The sidewall portions SWP may form an obtuse angle with respect to the upper end portions UP and the lower end portions LP and may extend from the upper end portions UP and the lower end portions LP. For example, the boundaries of the cover COP, the upper end portion UP, the lower end portion LP, and the sidewall portion SWP disposed adjacent to one another are illustrated by dotted lines in FIG. 23.

In an embodiment and referring to FIGS. 23 and 25, the covers COP may be integrally formed with the pattern part PTN and may extend from the pattern part PTN. The covers COP may extend from upper portions of the pattern part PTN in the first direction DR1 and may cover the first grooves GV1, respectively.

In an embodiment, when the covers COP are not used, the shape of the front surface of the pattern part PTN may be visible to the outside by the first grooves GV1. For example, since the first grooves GV1 extend in the second direction DR2, a stripe pattern extending in the second direction DR2 along the first grooves GV1 may be visible from the outside. In this case, the display quality of the display module DM may be deteriorated.

However, in an embodiment, the covers COP may be disposed to cover the first grooves GV1. In this case, due to the covers COP, the shape of the front surface of the pattern part PTN depending on the first grooves GV1 may not be visible to the outside. Thus, the display quality of the display module DM may be improved.

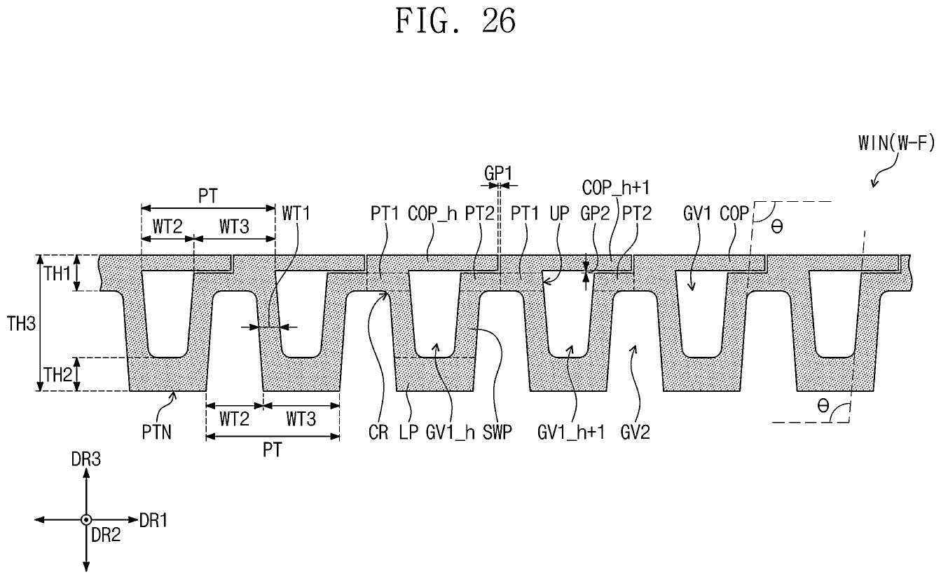

FIG. 26 is an enlarged view of a portion of the flexible window part illustrated in FIG. 23, according to an embodiment.

In an embodiment and referring to FIG. 26, the lower end portions LP may be arranged in the first direction DR1. The upper end portions UP may be disposed above the lower end portions LP and may be arranged in the first direction DR1. When viewed from above the plane, the upper end portions UP and the lower end portions LP may be alternately disposed in the first direction DR1. That is, when viewed from above the plane, one lower end portion LP may be disposed between two upper end portions UP to be located adjacent to each other, and one upper end portion UP may be disposed between two lower end portions LP to be located adjacent to each other.

In an embodiment, the sidewall portions SWP may extend from opposite ends of the lower end portions LP to opposite ends of the upper end portions UP. The sidewall portions SWP may extend to form an obtuse angle with the lower end portions LP and the upper end portions UP. The sidewall portions SWP may form an obtuse angle with the lower end portions LP and may extend upward from the opposite ends of the lower end portions LP to be located opposite to each other in the first direction DR1. In addition, the sidewall portions SWP may form an obtuse angle with the upper end portions UP and may extend downward from the opposite ends of the upper end portions UP opposite to each other in the first direction DR1.

In an embodiment, the first grooves GV1 may be defined by spaces between the lower end portions LP and the sidewall portions SWP. The second grooves GV2 may be defined by spaces between the upper end portions UP and the sidewall portions SWP. The widths of the first grooves GV1 in the first direction DR1 may be increased toward the top. The widths of the second grooves GV2 in the first direction DR1 may be increased toward the bottom. Depending on this structure, the pattern part PTN may extend in a zigzag pattern in the first direction DR1.

In an embodiment, the covers COP may be integrally formed with the upper end portions UP and may extend from the upper end portions UP. The covers COP may extend from the upper end portions UP and may cover the first grooves GV1.

In an embodiment and referring to FIG. 26, a portion of the window WIN disposed adjacent to one side of each of the first grooves GV1 in the first direction DR1 may be defined as a first portion PT1, and a portion of the window WIN disposed adjacent to an opposite side of the first groove GV1 in the first direction DR1 may be defined as a second portion PT2. That is, a portion of the window WIN disposed adjacent to one side of the hl first groove GV1_h in the first direction DR1 may be defined as a first portion PT1, and a portion of the window WIN disposed adjacent to an opposite side of the h^{th} first groove GV1_h in the first direction DR1 may be defined as a second portion PT2. Here, “h” is a natural number.

In an embodiment, each of the upper end portions UP of the pattern part PTN may include the first portion PT1 and the second portion PT2. For example, the boundaries between some of the first and second portions PT1 and PT2, respectively, and some of the covers COP and the boundaries between the upper end portion UP, the lower end portion LP, and the sidewall portion SWP disposed adjacent to one another are illustrated by dotted lines.

In an embodiment, the h^{th} cover COP_h may cover the hl first groove GV1_h. The h^{th} cover COP_h may extend from the first portion PT1 and may be disposed on the second portion PT2. The h^{th} cover COP_h may be integrally formed with the first portion PT1. The h^{th} cover COP_h may not make contact with the second portion PT2 and may be spaced apart from the second portion PT2 in the third direction DR3.

In an embodiment, the (h+1)^{th} cover COP_h+1 that covers the (h+1)^{th} first groove GV1_h+1 may extend from the first portion PT1 of the window WIN disposed adjacent to one side of the (h+1)^{th} first groove GV1_h+1 in the first direction DR1 and may be disposed on the second portion PT2 of the window WIN disposed adjacent to an opposite side of the (h+1)^{th} first groove GV1_h+1 in the first direction DR1.

In an embodiment, the h^{th} cover COP_h and the (h+1)^{th} cover COP_h+1 may be disposed adjacent to each other in the first direction DR1 to face each other and may be spaced apart from each other in the first direction DR1. One side of the h^{th} cover COP_h and one side of the (h+1)^{th} cover COP_h+1 that face each other may be disposed adjacent to each other and may be spaced apart from each other. The hi cover COP_h and the (h+1)^{th} cover COP_h+1 may be spaced apart from each other in the first direction DR1 and may not make contact with each other.

In an embodiment, the thickness of the pattern part PTN from the lower surface of the upper end portion UP to the upper surface of the cover COP in the third direction DR3 may be defined as a first thickness TH1. The thickness of the lower end portion LP in the third direction DR3 may be defined as a second thickness TH2. The distance between the bottom surface of the lower end portion LP and the upper surface of the cover COP in the third direction DR3 may correspond to the thickness of the flexible window part W-F and may be defined as a third thickness TH3.

In an embodiment, the first thickness TH1 may range from about 0.04 mm to about 0.06 mm and may preferably be about 0.05 mm. The second thickness TH2 may range from about 0.04 mm to about 0.06 mm and may preferably be about 0.05 mm. The third thickness TH3 may range from about 0.16 mm to about 0.24 mm and may preferably be about 0.2 mm.

In an embodiment, the width of the sidewall portion SWP in the first direction DR1 may be defined as a first width WT1. The maximum width of the first groove GV1 in the first direction DR1 may be defined as a second width WT2. In addition, the maximum width of the second groove GV2 in the first direction DR1 may also be defined as the second width WT2.

In an embodiment, the width of the pattern part PTN between two first grooves GV1 disposed adjacent to each other in the first direction DR1 may be defined as a third width WT3. In addition, the width of the pattern part PTN between two second grooves GV2 disposed adjacent to each other in the first direction DR1 may also be defined as the third width WT3. The third width WT3 may correspond to the width of the upper side of the upper end portion UP and the width of the lower side of the lower end portion LP in the first direction DR1.

In an embodiment, the distance between the sides of two first grooves GV1 disposed adjacent to each other in the first direction DR1 may be defined as a pitch PT. In addition, the distance between the sides of two second grooves GV2 disposed adjacent to each other in the first direction DR1 may also be defined as the pitch PT.

In an embodiment, the first width WT1 may range from about 0.024 mm to about 0.036 mm and may preferably be about 0.03 mm. The second width WT2 may range from about 0.08 mm to about 0.12 mm and may preferably be about 0.1 mm. The third width WT3 may range from about 0.084 mm to about 0.126 mm and may preferably be about 0.105 mm. The pitch PT may range from about 0.164 mm to about 0.246 mm and may preferably be about 0.205 mm.

In an embodiment, the gap between the h^{th} cover COP_h and the (h+1)^{th} cover COP_h+1 in the first direction DR1 may be defined as a first gap GP1. The gap between the second portion PT2 and the cover COP disposed on the second portion PT2 in the third direction DR3 may be defined as a second gap GP2.

In an embodiment, the first gap GP1 may be greater than about 0 and may be less than or equal to about 0.005 mm. The second gap GP2 may be greater than about 0 and may be less than or equal to about 0.005 mm.

In an embodiment, the angle θ formed by the lower end portion LP and the sidewall portion SWP may be greater than about 95 degrees and less than about 100 degrees. In addition, the angle θ formed by the upper end portion LP and the sidewall portion SWP may also be greater than about 95 degrees and less than about 100 degrees.

In an embodiment, an inner surface between the lower end portion LP and the sidewall portion SWP and an inner surface between the upper end portion UP and the sidewall portion SWP may be defined as curved surfaces CR. The radii of curvature of the curved surfaces CR may range from about 0.024 mm to about 0.034 mm and may preferably be about 0.029 mm.

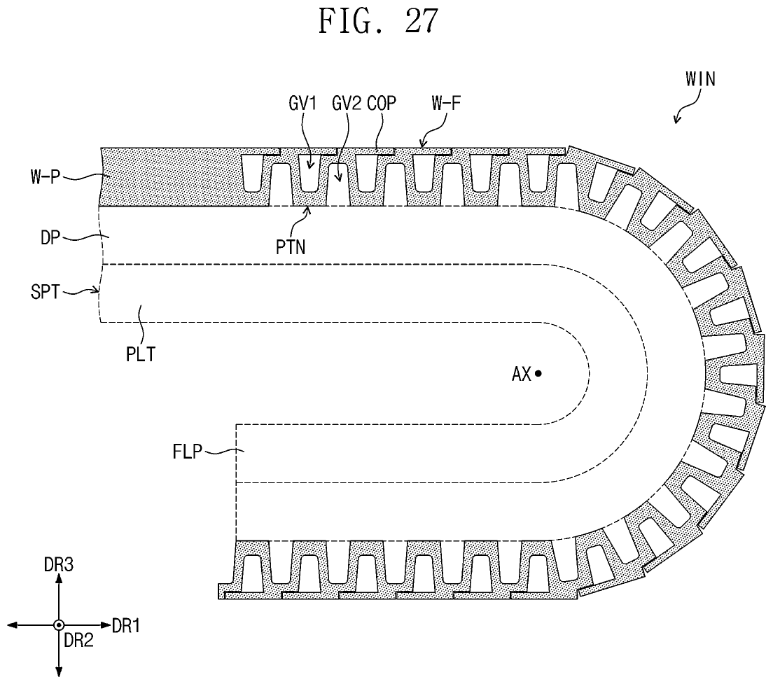

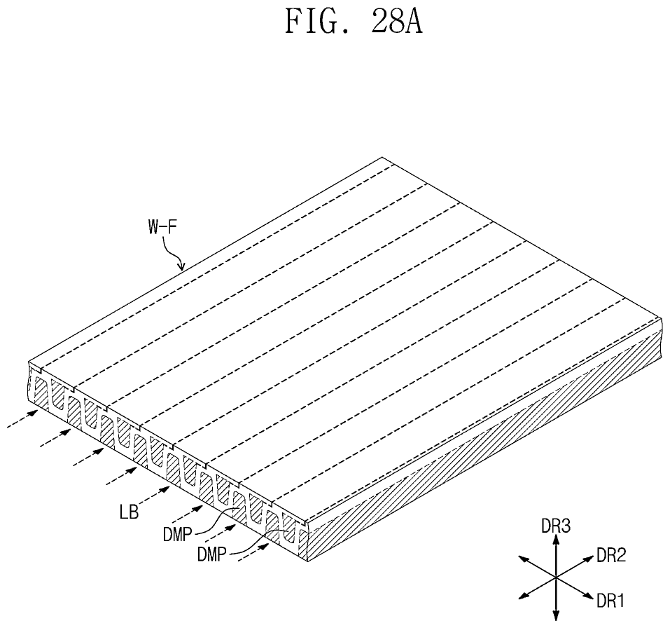

FIG. 27 is a view illustrating a folded state of the window illustrated in FIG. 23, according to an embodiment.

In FIG. 27, the display panel DP and the support plate SPT are illustrated by dotted lines together with the window WIN.

In an embodiment and referring to FIG. 27, the window WIN may be disposed on the front surface of the display panel DP, and the support plate SPT may be disposed on the rear surface of the display panel DP. The window WIN may be folded together with the display panel DP and the support plate SPT. The window WIN, the display panel DP, and the support plate SPT may be folded and accommodated in the above-described case CS.

In an embodiment, the flat part PLT of the support plate SPT may overlap the flat window part W-P. The flexible part FLP of the support plate SPT may overlap the flexible window part W-F. The flexible window part W-F may be folded such that a portion of the flexible window part W-F is disposed under the flat window part W-P. The flexible part FLP may be folded together with the flexible window part W-F.

In an embodiment, the flexible window part W-F may be folded about the axis AX extending in the second direction DR2. The first gap GP1 may range from about 0.005 mm to about 0.01 mm in the folded state of the flexible window part W-F.

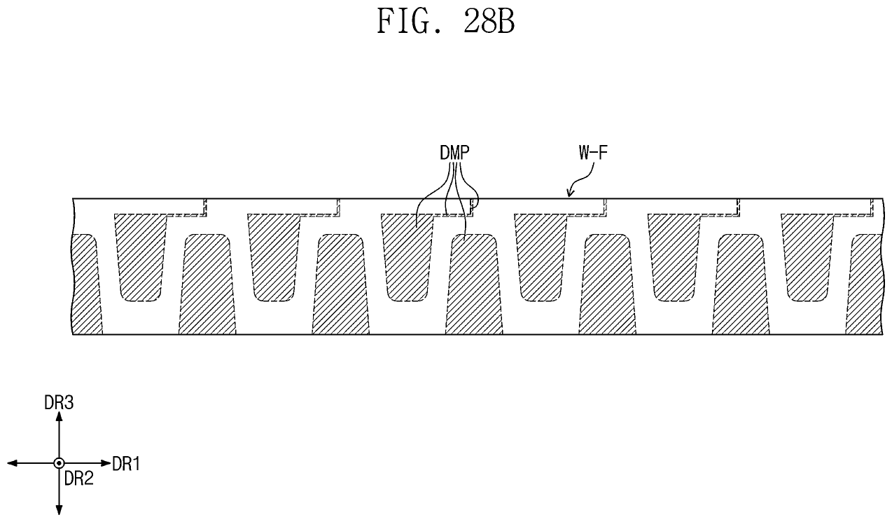

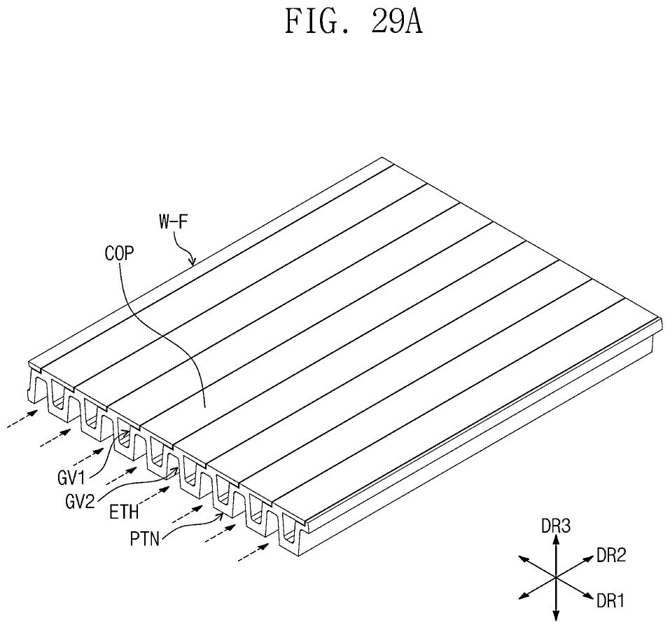

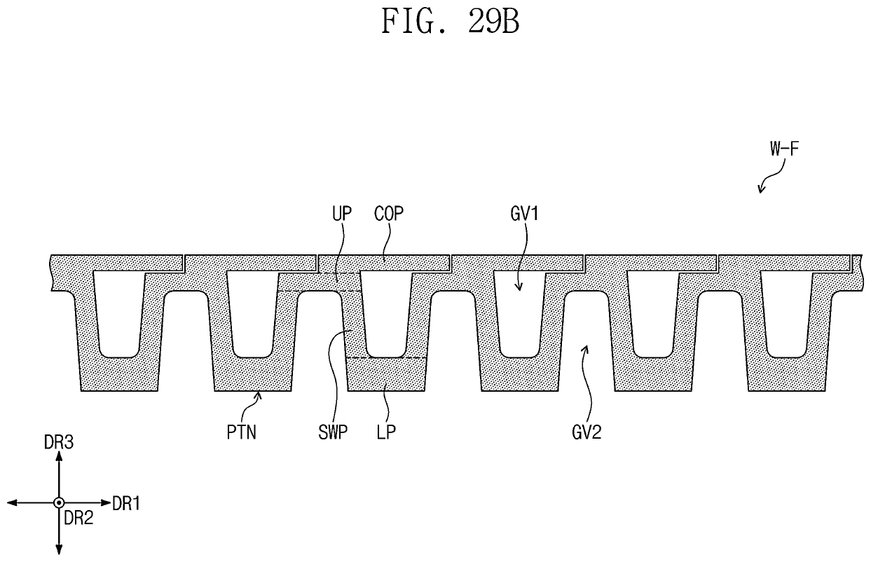

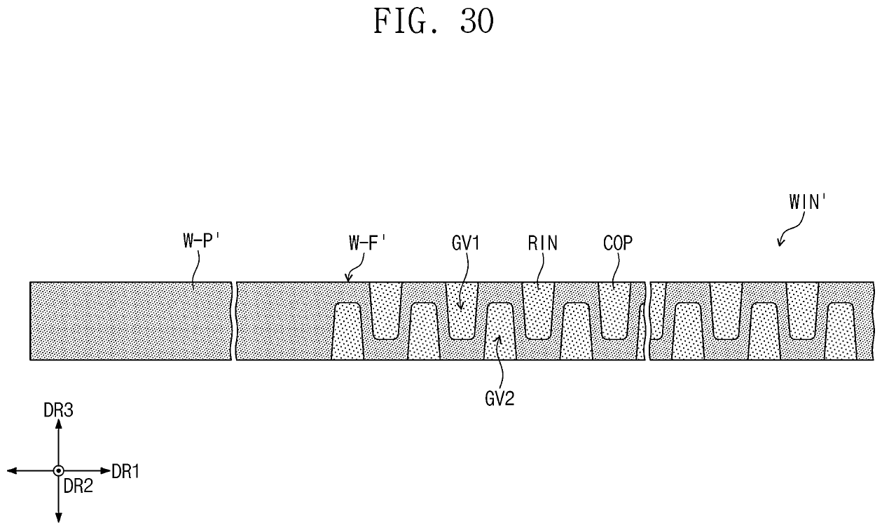

FIGS. 28A, 28B, 29A, and 29B are views for explaining a window manufacturing method, according to an embodiment.

FIGS. 28A and 28B illustrate a perspective view and a side view corresponding to FIGS. 25 and 26, and FIGS. 29A and 29B illustrate a perspective view and a side view corresponding to FIGS. 25 and 26, according to embodiments. In an embodiment, when the window WIN is manufactured, the flat window part W-P is not processed, and the flexible window part W-F is processed. Therefore, the flexible window part W-F is illustrated, and a method of processing the flexible window part W-F will be described.

In an embodiment and referring to FIGS. 28A and 28B, the unprocessed flexible window part W-F may be prepared, and a laser beam LB may be applied toward a side surface of the flexible window part W-F. The energy of the laser beam LB may be about 800nJ, and the width of the flexible window part W-F in the second direction DR2 may range from about 150 mm to about 200 mm. The laser beam LB may be provided from one side surface of the flexible window part W-F to an opposite side surface of the flexible window part W-F.

In an embodiment, the region to which the laser beam LB is provided may be the region in which the first grooves GV1 and the second grooves GV2 described above are formed. Furthermore, the region to which the laser beam LB is provided may be the portion between the one side of the hl cover COP_h and the one side of the (h+1)^{th} cover COP_h+1 that corresponds to the first gap GP1. In addition, the region to which the laser beam LB is provided may be the portion between the first portion PT1 of the (h+1)^{th} upper end portion UP and the hl cover COP_h that corresponds to the second gap GP2 (illustrated in FIG. 26).

In an embodiment, the portions of the flexible window part W-F to which the laser beam LB is applied may be damaged. The portions of the flexible window part W-F to which the laser beam LB is applied may be defined as damaged portions DMP. The damaged portions DMP may significantly react to an etchant.

In an embodiment and referring to FIGS. 29A and 29B, the etchant ETH may be provided to the flexible window part W-F. The damaged portions DMP may be removed by the etchant ETH. For example, the etchant ETH may be sodium hydroxide (NaOH), and the damaged portions DMP may be removed by the etchant ETH at a temperature of 80 degrees Celsius (° C.) to 90 degrees Celsius (° C.).

The first grooves GV1 and the second grooves GV2 may be defined in the flexible window part W-F by the removal of the damaged portions DMP. In addition, the first gap GP1 (illustrated in FIG. 26) and the second gap GP2 (illustrated in FIG. 26) may be defined in the flexible window part W-F by the removal of the damaged portions DMP (illustrated in FIGS. 28A and 28B).

FIG. 30 is a view illustrating a comparison window example, according to an embodiment.

FIG. 30 is a side view corresponding to FIG. 23.

In an embodiment and referring to FIG. 30, the comparison window WIN′ may include a flat window part W-P′ and a flexible window part W-F′. The flat window part W-P′ may have the same configuration as the flat window part W-P illustrated in FIG. 23. A plurality of first grooves GV1 may be defined on the upper surface of the flexible window part W-F′, and a plurality of second grooves GV2 may be defined on the lower surface of the flexible window part W-F′.

In an embodiment, the comparison window WIN′ may further include a resin layer RIN disposed in the first and second grooves GV1 and GV2, respectively. Since the resin layer RIN is disposed in the first and second grooves GV1 and GV2, respectively, the upper and lower surfaces of the comparison window WIN′ may be flat. However, a pattern depending on the first grooves GV1 may be visible due to a difference in physical properties between the resin layer RIN and the comparison window WIN′.

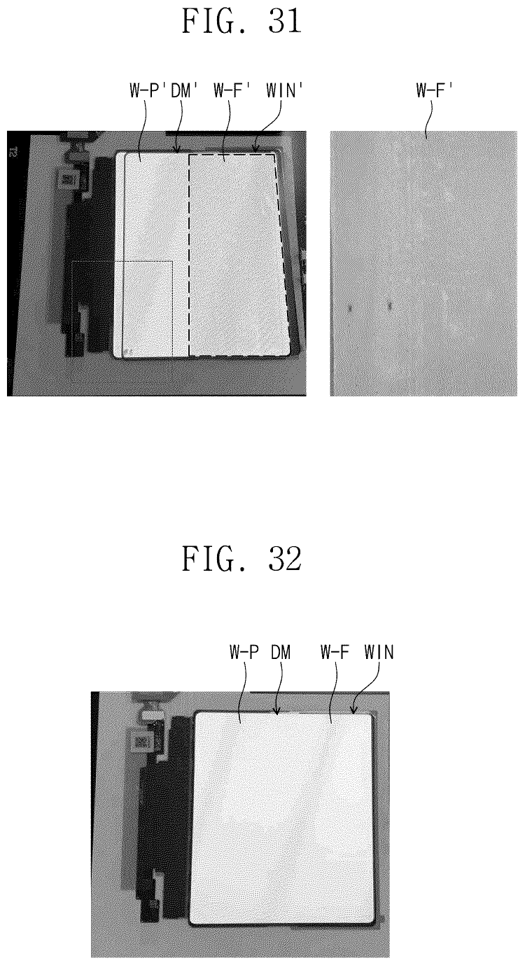

According to an embodiment, FIG. 31 illustrates an image of a front surface of a display module including the comparison window illustrated in FIG. 30. FIG. 32 illustrates an image of the front surface of the display module including the window illustrated in FIG. 23, according to an embodiment.

The images illustrated in FIGS. 31 and 32 are images of the display modules DM′ and DM in a flat state, according to an embodiment.

In an embodiment and referring to FIG. 31, when the comparison window WIN′ is used, the pattern of the flexible window part W-F′, depending on the first grooves GV1, may be visible due to the difference in physical properties between the resin layer RIN and the comparison window WIN′. For example, the pattern of the flexible window part W-F′ may be visible due to a difference in refractive index between the resin layer RIN and the comparison window WIN′.

In an embodiment and referring to FIG. 32, when the window WIN is used, the pattern of the flexible window part W-F depending on the first grooves GV1 may not be visible due to the covers COP. In a flat state of the window WIN, the first gap GP1 may be less than or equal to about 0.005 mm as described with reference to FIG. 26. FIG. 32 may illustrate an image of the front surface of the display module DM when the first gap GP1 is less than or equal to about 0.005 mm. Accordingly, the pattern of the flexible window part W-F may not be visible when the first gap GP1 is set to about 0.005 mm or less.

In an embodiment, when the flexible window part W-F is folded, the first gap GP1 may be increased to about 0.005 mm or more in a folded portion. However, since the folded portion of the display module DM is accommodated in the case CS and is not exposed to the outside as illustrated in FIGS. 21 and 22, the folded portion of the flexible window part W-F may also be accommodated in the case CS and may not be exposed to the outside.

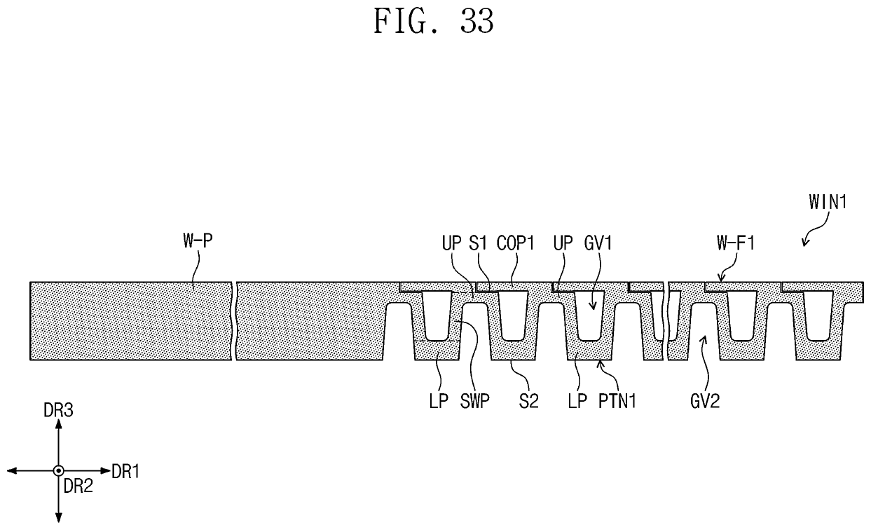

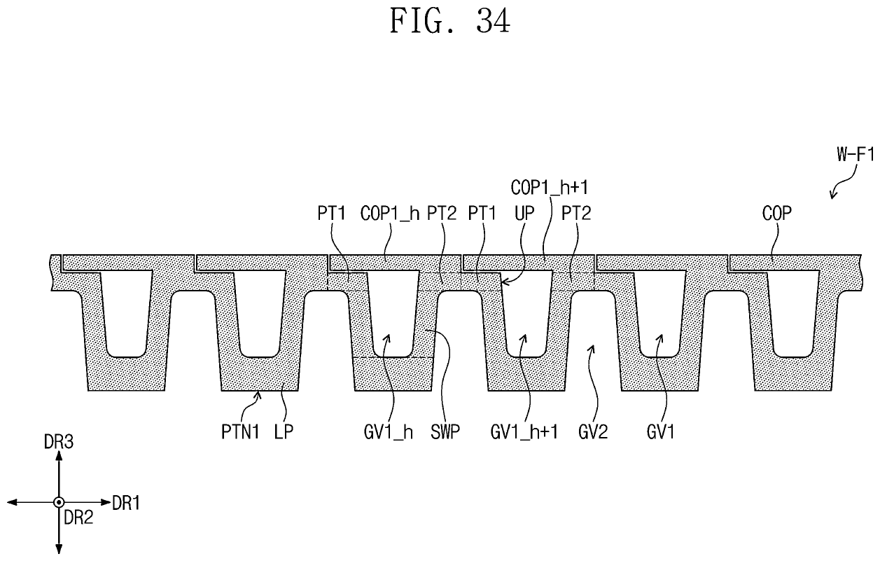

FIG. 33 is a view illustrating a configuration of a window, according to an embodiment. FIG. 34 is an enlarged view of a portion of a flexible window part illustrated in FIG. 33, according to an embodiment.

FIGS. 33 and 34 are a side view and an enlarged view corresponding to FIGS. 23 and 26.

The following description will be focused on a difference between the window WIN illustrated in FIGS. 23 and 26 and the window WIN1 illustrated in FIGS. 33 and 34.

In an embodiment and referring to FIGS. 33 and 34, first grooves GV1 and second grooves GV2 may be defined in the flexible window part W-F1, and covers COP1 may cover the first grooves GV1. The covers COP1 may be integrally formed with a pattern part PTN1 and may extend from the pattern part PTN1.

In an embodiment, the h^{th} cover COP1_h may cover the hl first groove GV1_h. The h^{th} cover COP1_h may extend from a second portion PT2 and may be disposed on a first portion PT1. The hl cover COP1_h may be integrally formed with the second portion PT2. The h^{th} cover COP1_h may not make contact with the first portion PT1 and may be spaced apart from the first portion PT1 in the third direction DR3.

In an embodiment, the (h+1)^{th} cover COP1_h+1 that covers the (h+1)^{th} first groove GV1_h+1 may extend from a second portion PT2 of the window WIN1 disposed adjacent to an opposite side of the (h+1)^{th} first groove GV1_h+1 in the first direction DR1 and may be disposed on a first portion PT1 of the window WIN1 disposed adjacent to one side of the (h+1)^{th} first groove GV1_h+1 in the first direction DR1.

In an embodiment, the hl cover COP1_h and the (h+1)^{th} cover COP1_h+1 may be disposed adjacent to each other in the first direction DR1 to face each other and may be spaced apart from each other in the first direction DR1. The hl cover COP1_h and the (h+1)^{th} cover COP1_h+1 may be spaced apart from each other in the first direction DR1 and may not make contact with each other.

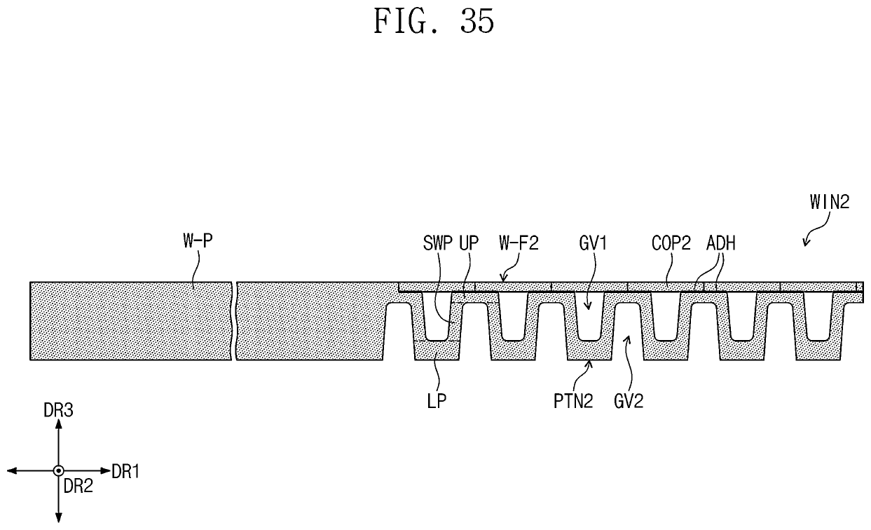

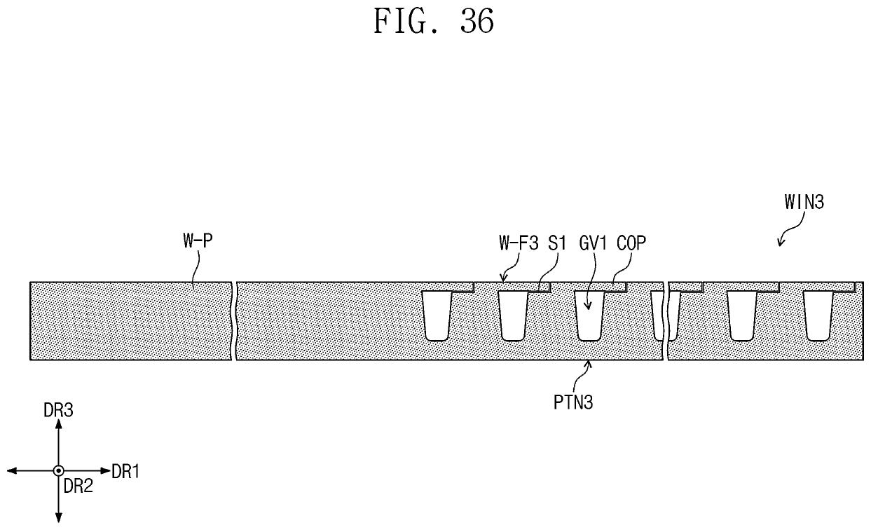

FIG. 35 is a view illustrating a configuration of a window, according to an embodiment.

FIG. 35 is a side view corresponding to FIG. 23. The following description will be focused on a difference between the window WIN illustrated in FIG. 23 and the window WIN2 illustrated in FIG. 35.

In an embodiment and referring to FIG. 35, first grooves GV1 and second grooves GV2 may be defined in a flexible window part W-F2, and covers COP2 may cover the first grooves GV1. The covers COP2 may be separated from a pattern part PTN2.

In an embodiment, the covers COP2 may be separated from upper end portions UP and may be disposed on the upper end portions UP to cover the first grooves GV1. The covers COP2 may be attached to the upper end portions UP. Adhesive layers ADH may be disposed between the covers COP2 and the upper end portions UP, and the covers COP2 may be attached to the upper end portions UP by the adhesive layers ADH.

FIG. 36 is a view illustrating a configuration of a window, according to an embodiment.

FIG. 36 is a side view corresponding to FIG. 23. The following description will be focused on a difference between the window WIN illustrated in FIG. 23 and the window WIN3 illustrated in FIG. 36.

In an embodiment and referring to FIG. 36, first grooves GV1 may be defined in a flexible window part W-F3. Unlike in the embodiment illustrated in FIG. 23, the second grooves GV2 may not be defined in the flexible window part W-F3. Since the first grooves GV1 are defined, the flexible window part W-F3 may be more flexible than a flat window part W-P. When the second grooves GV2 are additionally defined in the flexible window part W-F3 as illustrated in FIG. 23, the flexible window part W-F3 may be more flexible than when the second grooves GV2 are not defined in the flexible window part W-F3.

According to the embodiments of the invention, the flexible window part includes the pattern part having the first grooves defined therein. Accordingly, the flexible window part may be easily folded together with the display panel. In addition, the flexible window part includes the covers that cover the first grooves. Accordingly, visibility of the pattern part that is likely to be caused by the first grooves may be prevented.

Although the disclosure has been made above with reference to one or more embodiments of the invention, it may be understood that those skilled in the art or those having ordinary knowledge in the art may variously modify and change the invention without departing from the spirit and technical scope of the invention. Accordingly, the technical scope of the invention is not limited to the detailed description of the embodiments. Moreover, the embodiments or parts of the embodiments may be combined in whole or in part without departing from the scope of the invention.

What is claimed is:

1. A display device comprising:
a display panel;
a window disposed on the display panel, the window including a flat window part and a flexible window part extending from the flat window part, the flexible window part folded such that a portion of the flexible window part is disposed under the flat window part; and
a support plate disposed under the display panel,
wherein the flexible window part includes:
a pattern part including a first surface on which a first groove is defined and a second surface disposed opposite to the first surface, wherein the second surface faces the display panel; and
a cover covering the first groove.

2. The display device of claim 1, wherein the flat window part has a higher elastic modulus than the flexible window part.

3. The display device of claim 1, wherein the cover is integrally formed with the pattern part and extends from the pattern part.

4. The display device of claim 1, wherein a second groove disposed adjacent to the first groove is further defined on the second surface.

5. The display device of claim 1, wherein the first groove includes a plurality of first grooves and the second groove includes a plurality of second grooves, wherein the plurality of first grooves and the plurality of second grooves are alternately arranged with respect to each other to be directed in one direction, and
wherein the pattern part includes:
a plurality of lower end portions defined as portions of the pattern part below the plurality of first grooves;
a plurality of upper end portions disposed above the plurality of lower end portions and defined as portions of the pattern part above the plurality of second grooves; and
a plurality of sidewall portions defined as portions of the pattern part between the plurality of first grooves and the plurality of second grooves and forming an obtuse angle with respect to the plurality of upper end portions and the plurality of lower end portions.

6. The display device of claim 5, wherein the cover includes a plurality of covers, and wherein the plurality of covers are integrally formed with the plurality of upper end portions, and wherein the plurality of covers extend from the plurality of upper end portions.

7. The display device of claim 5, wherein a first portion of the window disposed adjacent to one side of an h^{th} first groove in the one direction and a second portion of the window disposed adjacent to an opposite side of the hl first groove in the one direction are defined, and
wherein an h^{th} cover covering the h^{th} first groove extends from the first portion of the window and is disposed on the second portion of the window, and h is a natural number.

8. The display device of claim 7, wherein the h^{th} cover is integrally formed with the first portion of the window.

9. The display device of claim 8, wherein the h^{th} cover is spaced apart from the second portion of the window.

10. The display device of claim 8, wherein an (h+1)^{th} cover covering an (h+1)^{th} first groove extends from a portion of the window disposed adjacent to one side of the (h+1)^{th} first groove, and
wherein the h^{th} cover and the (h+1)^{th} cover are disposed adjacent to each other in the one direction to face each other and are spaced apart from each other in the one direction.

11. The display device of claim 10, wherein a gap between the h^{th} cover and the (h+1)^{th} cover in the one direction is greater than about 0 and less than or equal to about 0.005 mm.

12. The display device of claim 5, wherein a first portion of the window disposed adjacent to one side of an h^{th} first groove in the one direction and a second portion of the window disposed adjacent to an opposite side of the h^{th} first groove in the one direction are defined, and
wherein an h^{th} cover covering the hl first groove extends from the second portion of the window and is disposed on the first portion of the window, and wherein h is a natural number.

13. The display device of claim 12, wherein the h^{th} cover is integrally formed with the second portion of the window and spaced apart from the first portion of the window.

14. The display device of claim 5, wherein the cover includes a plurality of covers, wherein the plurality of covers are separated from the plurality of upper end portions and disposed on the plurality of upper end portions.

15. The display device of claim 14, further comprising:
an adhesive layer disposed between the plurality of covers and the plurality of upper end portions.

16. The display device of claim 1, wherein the flexible window part extends from the flat window part in a first direction and is folded about an axis extending in a second direction crossing the first direction, and
wherein the pattern part extends in a zigzag pattern in the first direction.

17. The display device of claim 16, wherein the support plate includes:
a flat part overlapping the flat window part; and
a flexible part overlapping the flexible window part, wherein the flexible part extends from the flat part and is folded together with the flexible window part.

18. The display device of claim 17, further comprising:
a plurality of support bars disposed under the flexible part, wherein the plurality of support bars are arranged in the first direction and extend in the second direction;
a plurality of link bars coupled to opposite ends of the plurality of support bars, wherein the opposite ends of the plurality of support bars are disposed opposite to each other in the second direction;
a case accommodating the display panel, the window, and the support plate; and
guide rails connected to inner surfaces of the case, the inner surfaces being disposed to face each other in the second direction,
wherein the link bars are coupled to the guide rails and move along the guide rails.

19. A display device comprising:
a display panel; and
a window disposed on the display panel,
wherein the window includes:
a flat window part;
a pattern part extending from the flat window part, the pattern part including a first surface on which a first groove is defined and a second surface disposed opposite to the first surface, wherein the second surface faces the display panel; and
a cover covering the first groove.

20. The display device of claim 19, wherein the cover is integrally formed with the pattern part and extends from the pattern part.
